(19) United States
(12) Patent Application Publication
(10) Pub. No.: US 2023/0420437 A1
(43) Pub. Date: Dec. 28, 2023

(54) THREE DIMENSIONAL (3D) CHIPLET AND METHODS FOR FORMING THE SAME

(71) Applicant: Taiwan Semiconductor Manufacturing Company Limited, Hsinchu (TW)

(72) Inventors: Chieh-Yen Chen, Taipei City (TW); Jeng-Shien Hsieh, Kaohsiung (TW); Chuei-Tang Wang, Taichung City (TW); Chen-Hua Yu, Hsinchu city (TW)

(21) Appl. No.: 17/847,335

(22) Filed: Jun. 23, 2022

(51) Int. Cl. H01L 25/18; H01L 25/065; H01L 23/00; H01L 25/00; H01L 21/768

(52) U.S. Cl. CPC H01L 25/18; H01L 25/0657; H01L 24/92; H01L 25/50; H01L 24/83; H01L 21/76898; H01L 2225/06524; H01L 2225/06544; H01L 2225/06565; H01L 24/29; H01L 2224/29186; H01L 2924/05442; H01L 24/32; H01L 2224/32; H01L 24/08; H01L 2224/08145; H01L 2224/9222; H01L 24/02; H01L 2224/02372; H01L 2224/05647; H01L 2224/05639; H01L 2224/05671; H01L 2224/05655; H01L 2224/05611; H01L 2224/05684; H01L 2224/05666; H01L 2224/05644; H01L 24/80; H01L 2224/80203; H01L 2224/8083; H01L 2224/80379; H01L 2924/0665; H01L 2924/07025; H01L 2924/06; H01L 2224/8085; H01L 2224/8089; H01L 2224/80905; H01L 2224/83203; H01L 2224/83931; H01L 2224/8389; H01L 2924/1431; H01L 2924/1432; H01L 2924/1433; H01L 2924/1434

(57) ABSTRACT

A semiconductor structure, includes a logic die, a memory die stack bonded to the logic die by a first oxide bond, and including a first pair of memory dies bonded together by a first direct bond, and a first through silicon via (TSV) in the logic die and extending across the first oxide bond and electrically connecting the logic die to the first pair of memory dies.

### BACKGROUND

Compute-in-memory (CIM) and compute-near-memory (CNM) architectures are emerging to boost energy-efficient computing for edge accelerators. However, typical monolithic three-dimensional integrated circuit (3DIC) may not be feasible for such memory architecture implementations. In particular, a two-dimensional (2D) system on chip (SoC) design and implementation of CIM architecture may suffer the device nodes' mismatch challenges of a non-volatile memory (NVM) function block and the control logic block. Further, three-dimensional (3D) stacked chips by microbump (ubump) technology may not be able to fulfill the interconnect density requirements for CIM architecture partitioning and re-integrating.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first chiplet (e.g., a 3D chiplet, top chiplet, etc.) according to one or more embodiments.

FIG. 2A is a vertical cross-sectional view of the first memory die, second memory die and logic die, according to one or more embodiments.

FIG. 2B is a vertical cross-sectional view of the first memory die on a carrier substrate, according to one or more embodiments.

FIG. 2C is a vertical cross-sectional view of the memory die stack on the carrier substrate, according to one or more embodiments.

FIG. 2D is a vertical cross-sectional view of the oxide layer on the memory die stack, according to one or more embodiments.

FIG. 2E is a vertical cross-sectional view of the oxide layer on the logic die, according to one or more embodiments.

FIG. 2F is a vertical cross-sectional view of the logic die bonded to the memory die stack, according to one or more embodiments.

FIG. 2G is a vertical cross-sectional view of the logic die and memory die stack after detaching the carrier substrate, according to one or more embodiments.

FIG. 2H is a vertical cross-sectional view of the logic die and memory die stack after forming the TSV, according to one or more embodiments.

FIG. 2I is a vertical cross-sectional view of the logic die and memory die stack after forming the connecting structure, according to one or more embodiments.

FIG. 3 is a flow chart illustrating a method of forming a first chiplet, according to various embodiments.

FIG. 4 is a vertical cross-sectional view of semiconductor device including the first chiplet, according to one or more embodiments.

FIG. 5 is a vertical cross-sectional view of a second chiplet (e.g., a 3D chiplet, top chiplet, etc.) according to one or more embodiments.

FIG. 6A is a vertical cross-sectional view of the logic die after forming the oxide layer, according to one or more embodiments.

FIG. 6B is a vertical cross-sectional view of the third memory die after forming the oxide layer, according to one or more embodiments.

FIG. 6C is a vertical cross-sectional view of a die stack, according to one or more embodiments.

FIG. 6D is a vertical cross-sectional view of the first memory die after forming the oxide layer, according to one or more embodiments.

FIG. 6E is a vertical cross-sectional view of the second memory die after forming the oxide layer, according to one or more embodiments.

FIG. 6F is a vertical cross-sectional view of a memory die stack, according to one or more embodiments.

FIG. 6G is a vertical cross-sectional view of an intermediate structure after forming a direct bond, according to one or more embodiments.

FIG. 6H is a vertical cross-sectional view of an intermediate structure after forming the first TSV and second TSV, according to one or more embodiments.

FIG. 6I is a vertical cross-sectional view of the intermediate structure after forming the connecting structure, according to one or more embodiments.

FIG. 7 is a flow chart illustrating a method of forming a second chiplet, according to various embodiments.

FIG. 8 is a vertical cross-sectional view of semiconductor device including the second chiplet, according to one or more embodiments.

FIG. 9 is a vertical cross-sectional view of a third chiplet (e.g., a 3D chiplet, top chiplet, etc.) according to one or more embodiments.

FIG. 10A is a vertical cross-sectional view of the first memory die, according to one or more embodiments.

FIG. 10B is a vertical cross-sectional view of a memory die stack (first memory die stack), according to one or more embodiments.

FIG. 10C is a vertical cross-sectional view of the fourth memory die, according to one or more embodiments.

FIG. 10D is a vertical cross-sectional view of a memory die stack (second memory die stack), according to one or more embodiments.

FIG. 10E is a vertical cross-sectional view of a memory die stack, according to one or more embodiments.

FIG. 10F is a vertical cross-sectional view of the memory die stack after forming the oxide layer, according to one or more embodiments.

FIG. 10G is a vertical cross-sectional view of an intermediate structure after forming the oxide bond, according to one or more embodiments.

FIG. 10H is a vertical cross-sectional view of the logic die after forming the oxide layer, according to one or more embodiments.

FIG. 10I is a vertical cross-sectional view of an intermediate structure after he forming of the oxide layer, according to one or more embodiments.

FIG. 10J is a vertical cross-sectional view of an intermediate structure after forming the oxide bond, according to one or more embodiments.

FIG. 10K is a vertical cross-sectional view of an intermediate structure after forming the first TSV and second TSV, according to one or more embodiments.

FIG. 10L is a vertical cross-sectional view of the intermediate structure after forming the connecting structure, according to one or more embodiments.

FIG. 11 is a flow chart illustrating a method of forming a third chiplet, according to various embodiments

FIG. 12 is a vertical cross-sectional view of semiconductor device including the third chiplet, according to one or more embodiments.

FIG. 13 is a vertical cross-sectional view of a fourth chiplet (e.g., a 3D chiplet, top chiplet, etc.) according to one or more embodiments.

FIG. 14 is a vertical cross-sectional view of semiconductor device including the fourth chiplet, according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

It may be desirable to integrate CIM architectures and CIM-based accelerators with existing main processors and artificial intelligence (AI) accelerators. In particular, it may be desirable to integrate CIM architectures and CIM-based accelerators with central processing units (CPUs), graphics processing units (GPUs), field-programmable gate arrays (FPGAs), application-specific integrated circuits (ASICs), etc.

One or more embodiments of the present disclosure may include an interconnect scheme for a 3D chiplet architecture. Compute-in-memory (CIM) and compute-near-memory (CNM) architectures are emerging to boost energy-efficient computing for edge accelerators. Versatile NVM technologies demonstrate complementary metal oxide semiconductor (CMOS) compatibility and performance scalability for analog CIM architectures. The partitioning of the CIM architecture and heterogeneous re-integration by a high-density system of integrated chips (SoIC) bond technology may provide performance benefits such as energy efficiency and computing efficiency. The proposed architecture (e.g., CIM architecture) and compact interconnect schemes between control logic tiers and volatile memory/non-volatile memory (VM/NVM) tiers of various embodiments disclosed herein may provide process flexibility to implement a CIM chiplet.

One or more embodiments of the present disclosure may include a semiconductor structure including a wafer-on-wafer (WoW) stacked memory and control tiers with simplified interconnect data links. In the first embodiment, two memory wafers (e.g., first memory wafer and second memory wafer) may be stacked on a logic wafer. In an embodiment, through silicon vias (TSVs) may be absent in the original memory wafers (e.g., prior to stacking the first memory wafer and second memory wafer), which may simplify the structures of the memory wafers.

In particular, the first memory die may be devoid of an inner TSV extending through more than two dielectric layers of the first memory die to a dielectric layer in the second memory die. In addition, or in the alternative, the second memory die may be devoid of an inner TSV extending through more than two dielectric layers of second memory die to a dielectric layer in the first memory die. Instead of having an inner TSV in the first memory die and/or second memory die, the semiconductor structure may include a TSV in the logic die (a first TSV) that may serve as an exclusive data path between the first memory die and the logic die, and between the second memory die and the logic die.

In another embodiment, three memory wafers (e.g., first memory wafer, second memory wafer and third memory wafer) may be stacked on a logic wafer. In an embodiment, through silicon vias (TSVs) may be absent in the three original memory wafers prior to stacking. In another embodiment, four memory wafers (e.g., first memory wafer, second memory wafer, third memory wafer, and further memory wafer) may be stacked on a logic wafer. In an embodiment, through silicon vias (TSVs) may be absent in the four original memory wafers prior to stacking.

One or more embodiments may include a combination of one or more bonds (e.g., wafer-on-wafer (WoW) face-to-face (F2F) direct bonds (e.g., SoIC bonds), WoW back-to-back (B2B) oxide bonds, etc.) to form the proposed chiplet architecture. Interconnect schemes by TSVs and back end of line (BEOL) processes may be used to provide short data links between the control logic and memory tiers in the first, second and third embodiments, and to implement individual links to the memory wafers (e.g., first, second, third and fourth memory wafers) in the fourth embodiment.

One or more embodiments may have several advantages. The embodiments may allow a low power and high memory capacity CIM chiplet architecture to be achieved with direct-bonded and oxide-bonded WoW tiers. The embodiments may allow a CMOS-compatible volatile memory and non-volatile memory to be integrated by the proposed chiplet architecture to achieve desired synaptic properties for analog CIM and digital CIM/CNM architectures. The proposed CIM/CNM chiplet architectures may further be integrated into a base chiplet of CPUs, GPUs, FPGAs, and/or network chips to enhance an overall computing force and to enable multiple accelerating dataflow and functionality of artificial intelligence/deep neural network (AI/DNN) chips.

In short, the various embodiments of the proposed architecture may include a top die chiplet. A chip-on-wafer (CoW) of the top die chiplet may be mounted on a base die chiplet with a direct bond (e.g., SoIC bond) to form the overall chip. The top die chiplet may be WoW stacked memory and logic tiers, and may work as a co-processor, accelerator, or on-chip memory buffer for the base die. The base die chiplet may be a versatile CPU, GPU, FPGA, networking chip, AI DNN accelerator, etc.

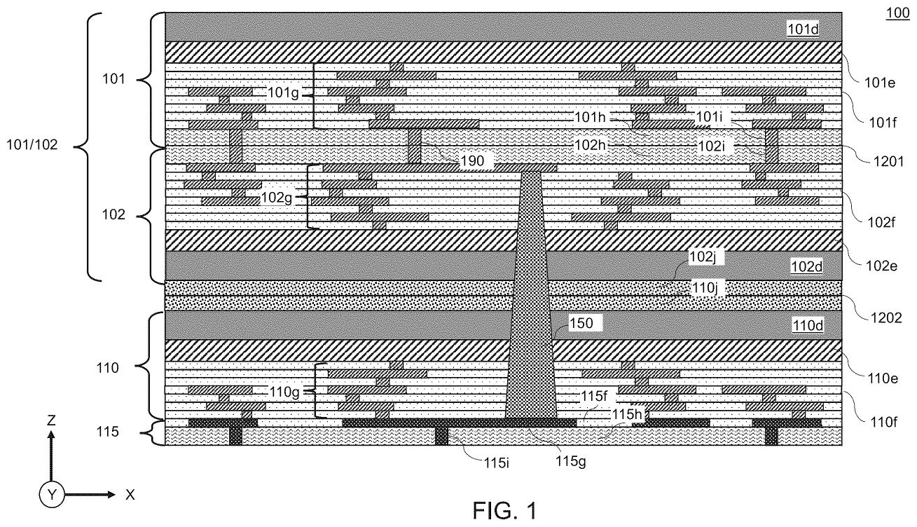

FIG. 1 is a vertical cross-sectional view of a first chiplet 100 (e.g., a 3D chiplet, top chiplet, etc.) according to one or more embodiments. The first chiplet 100 may include a logic die 110 and a memory die stack 101/102 stacked on the logic die 110. The memory die stack 101/102 may include a first memory die 101 stacked on a second memory die 102. The first memory die 101 may have a structure and function that is substantially the same as the structure and function of the second memory die 102. The first memory die 101 may alternatively have a structure and function that is different than the structure and function of the second memory die 102.

The first memory die 101 may include a semiconductor substrate 101d. The semiconductor substrate 101d may include, for example, silicon, germanium, silicon germanium, or other suitable semiconductor material. In the first chiplet 100, relative to the logic die 110, the first memory die 101 may have an inverted orientation. That is, the first memory die 101 may be arranged so that the semiconductor substrate 101d is on a side of the first memory die 101 that is opposite the logic die 110. It may be said, for example, that the first memory die 101 “faces” the logic die 110.

The first memory die 101 may include an active region 101e (e.g., front end of line (FEOL) region) on the semiconductor substrate 101d. The active region 101e may include, for example, volatile memory (VM) devices and/or non-volatile memory (NVM) devices. In particular, the active region 101e may include one or more memory circuits with one or more memory devices. The active region 101e may include, for example, one or more memory arrays including a plurality of memory cells. The memory cells may include, for example, transistors for storing data.

An interlayer dielectric 101f (e.g., back end of line (BEOL) region) may be located on the active region 101e. The interlayer dielectric 101f may include a plurality of dielectric layers. The dielectric layers may include, for example, SiO₂, a dielectric polymer or other suitable dielectric material. The interlayer dielectric 101f may include one or more metal interconnect structures 101g formed therein. The metal interconnect structures 101g may include metal traces and metal vias formed in the dielectric layers and provide an electrical connection to the active region 101e (e.g., the memory devices in the active region). The metal interconnect structures 101g may include, for example, copper or another suitable metal (e.g., silver, chromium, nickel, tin, tungsten, titanium, gold, etc.), a copper alloy, or other suitable metal alloy. A thickness of the first memory die 101 (e.g., including the semiconductor substrate 101d, active region 101e, and interlayer dielectric 101f that embeds metal interconnect structures 101g) may be, for example, in a range from about 1 μm to about 20 μm, although thicker or thinner thicknesses may be used.

The first memory die 101 may also include a bonding material layer 101h formed over (but appearing under in FIG. 1) the interlayer dielectric 101f. The bonding material layer 101h may include, for example, silicon oxide or binding polymers, such as an epoxy, a polyimide (PI), a benzocyclobutene (BCB), and a polybenzoxazole (PBO). Other suitable bonding layer materials may be within the contemplated scope of disclosure. One or more bonding pads 101i may be located in the bonding material layer 101h. The bonding pads 101i may include, for example, may include, for example, copper or another suitable metal (e.g., silver, chromium, nickel, tin, tungsten, titanium, gold, etc.), a copper alloy, or other suitable metal alloy.

Similar to the first memory die 101, the second memory die 102 may include a semiconductor substrate 102d similar to the semiconductor substrate 101d, an active region 102e similar to the active region 101e, an interlayer dielectric 102f similar to the interlayer dielectric 101f, and metal interconnect structures 102g similar to the metal interconnect structures 101g. The second memory die 102 may also include a bonding material layer 102h similar to the bonding material layer 101h and one or more bonding pads 102i (similar to the bonding pads 101i) in the bonding material layer 102h.

The first memory die 101 may be bonded to the second memory die 102 by a face-to-face (F2F) direct bond (e.g., hybrid bond) 1201. That is, a face of the first memory die 101 (e.g., a side of the first memory die 101 that is opposite the semiconductor substrate 101d) may be bonded to a face of the second memory die 102 (e.g., a side of the second memory die 102 that is opposite the semiconductor substrate 102d). The direct bond 1201 may include, for example, a dielectric-to-dielectric bond, a polymer-to-polymer bond, and/or a metal-to-metal bond. In particular, in the direct bond 1201, the bonding material layer 101h may be bonded to the bonding material layer 102h, and the one or more bonding pads 101i may be bonded to the one or more bonding pads 102i to form a bonding pad interconnect 190.

The logic die 110 may also include a semiconductor substrate 110d similar to the semiconductor substrate 101d. Similar to the first memory die 101, relative to the second memory die 102, the logic die 110 may have an inverted orientation. That is, the logic die 110 may be arranged so that the semiconductor substrate 110d is located above the components formed thereon.

The logic die 110 may include an active region 110e on the semiconductor substrate 110d. The active region 110e may include one or more logic circuits with one or more logic devices. The active region 110e may include, for example, CIM logic. The logic die 110 may also include an interlayer dielectric 110f similar to the interlayer dielectric 101f, and metal interconnect structures 110g similar to the metal interconnect structures 101g. The metal interconnect structures 101g may provide an electrical connection to the one or more logic circuits in the active region 110e.

The memory die stack 101/102 may be bonded to the logic die 110 by a back-to-back (B2B) oxide bond 1202. In the oxide bond 1202, an oxide layer 102j (e.g., SiO₂ layer) on a semiconductor substrate 102d of the second memory die 102 may be bonded to an oxide layer 110j (e.g., SiO₂ layer) on a semiconductor substrate 110d of the logic die 110.

The first chiplet 100 may also include a through silicon via (TSV) 150 that may provide an electrical connection within the first chiplet 100. The TSV 150 may be a singular TSV in the first chiplet 100. That is, prior to the assembly of the first chiplet 100, TSVs may be absent from the first memory die 101, second memory die 102 or logic die 110.

The TSV 150 may be located in the logic die 110 and extend across the oxide bond 1202 into the second memory die 102. The TSV 150 may contact a metal layer (e.g., metal trace) in the metal interconnect structure 102g which is connected to the active region 102e of the second memory die 102. Thus, data may be transmitted to and from the active region 102e (e.g., to and from the one or more memory circuits in the active region 102e) by the TSV 150.

In addition, the metal interconnect structure 102g may be connected across the direct bond 1201 to the metal interconnect structure 101g in the first memory die 101 by a connection (bonding pad interconnect 190) between one or more bonding pads 101i and one or more bonding pads 102i. Thus, data may be transmitted to and from the active region 101e (e.g., to and from the one or more memory circuits in the active region 101e) in the first memory die 101 by the TSV 150.

The TSV 150 may include, for example, copper or another suitable metal (e.g., silver, aluminum, chromium, nickel, tin, tungsten, titanium, gold, etc.), a copper alloy, an aluminum alloy or other suitable metal alloy. The TSV 150 may have a thickness in a z-direction in a range from about 1 μm to about 30 μm, although ticker or thinner thicknesses may be used depending on the thickness of the second memory die 102 and logic die 110.

The first chiplet 100 may also include a connecting structure 115 on the logic die 110. The connecting structure 115 may include a back end of line (BEOL) layer to connect the TSV 150 with a logic circuit in the logic die 110. The current sum data paths of the first memory die 101 and the second memory die 102 may thereby be combined at the logic die 110. The connecting structure 115 may also include bonding pad vias/bonding pad metal (BPV/BPM) for later chip-to-wafer (C2 W) assembly.

In particular, the connecting structure 115 may be on a face of the bonding structure that is opposite the semiconductor substrate 110d. The connecting structure 115 may allow the first chiplet 100 to be connected to another structure. In particular, the connecting structure 115 may allow the first chiplet 100 to be bonded and electrically connected to a base die.

The connecting structure 115 may include a dielectric layer 115f on the interlayer dielectric 110f of the logic die 110. The dielectric layer 115f may include SiO₂ or other suitable dielectric material. The dielectric material may be the same or different from interlayer dielectric 101f of the first memory die 101. The dielectric material may be the same or different from interlayer dielectric 102f of the second memory die 102. One or more metal layers 115g may be located in the dielectric layer 115f. The metal layers 115g may be connected to a metal interconnect structure 110g in the logic die 110 and connected to the TSV 150. Thus, data may be transmitted to and from the logic region 110e (e.g., to and from the one or more logic circuits in the active region 110e) in the logic die 110 by the TSV 150. The connecting structure 115 may also include a bonding material layer 115h and one or more bonding pads 115i.

The first chiplet 100 may include an efficient and effect interconnect scheme. The use of the TSV 150 (e.g., a single TSV formed in the first chiplet 100 after stacking the memory die stack 101/102 on the logic die 110), may simply the structures of the first memory die 101 and second memory die 102. The TSV 150 may provide a data link between the logic die 110 and the first memory die 101, and a data link between the logic die 110 and the second memory die 102. The TSV 150 may also combine a data path between the logic die 110 and the first memory die 101, and a data path between the logic die 110 and the second memory die 102. This combined data path may be especially useful, for example, for a hybrid VM/NVM synapse CIM architecture (e.g., where the first memory die 101 includes an metal-insulator-metal (MIM) capacitor and the second memory die 102 includes resistive random access memory (RRAM)). Further, a distance between the logic die 110 and the first memory die 101 may be substantially the same as a distance between the logic die 110 and the second memory die 102.

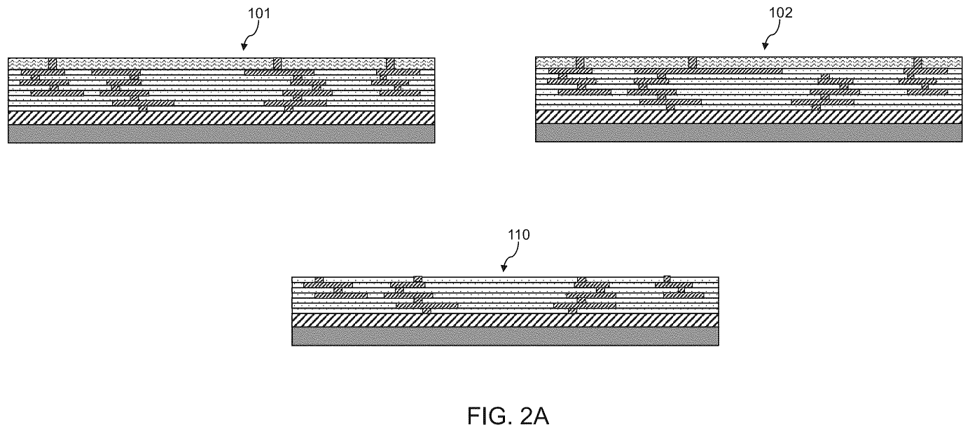

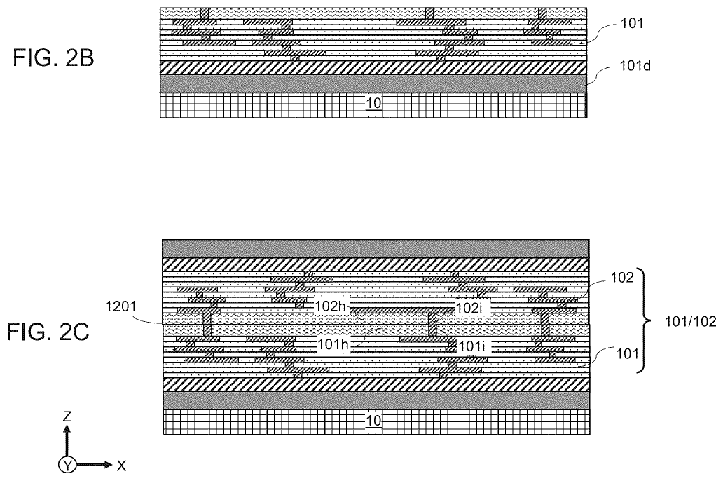

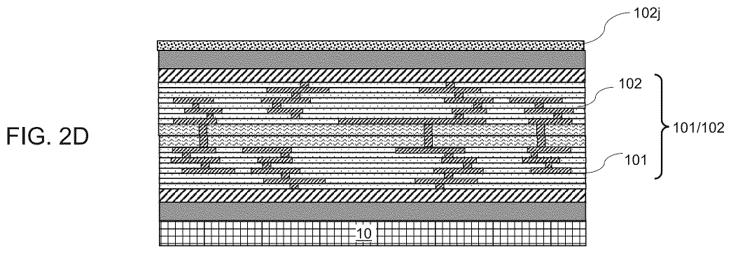

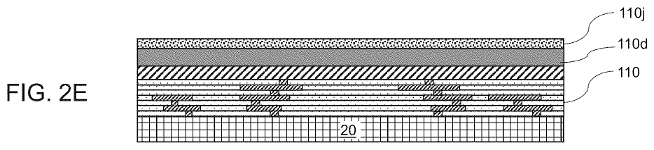

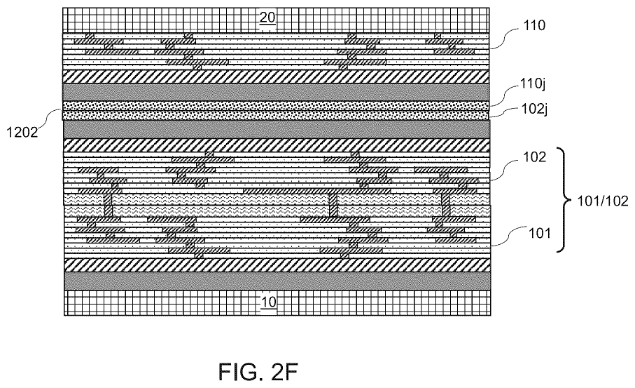

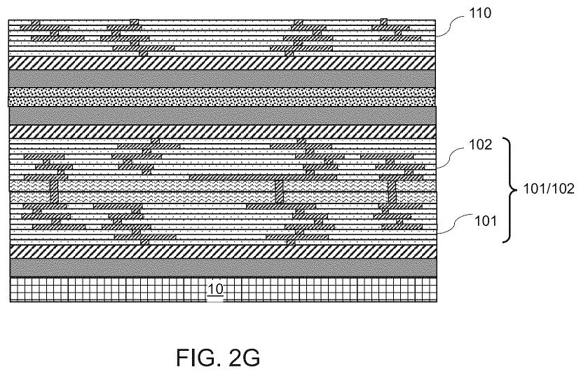

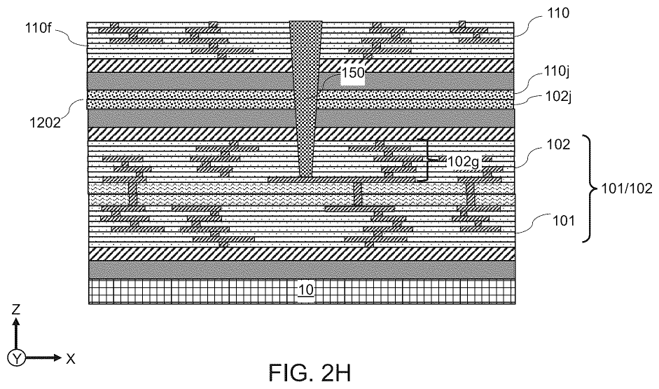

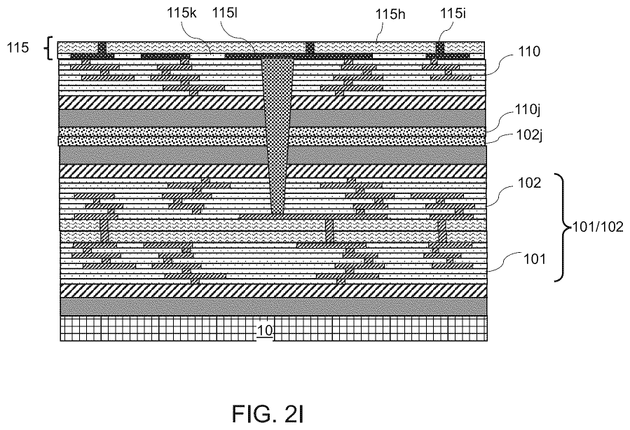

FIGS. 2A-21 are vertical cross-sectional views of various intermediate structures in a method of forming the first chiplet 100, according to one or more embodiments. In particular, FIG. 2A is a vertical cross-sectional view of the first memory die 101, second memory die 102 and logic die 110, according to one or more embodiments.

A method of forming the first chiplet 100 may begin with a forming of the first memory die 101, second memory die 102 and logic die 110. Each of the first memory die, second memory die and logic die 110 may be formed, for example, on a semiconductor wafer (e.g., silicon wafer). At least a portion of the method of forming the first chiplet 100 may be performed by wafer-on-wafer (WOW) processes. That is, the method of forming the first chiplet 100 may including a WOW process in which a semiconductor wafer containing the first memory die 101 may be bonded to a semiconductor wafer containing the second memory die 102, and so on.

FIG. 2B is a vertical cross-sectional view of either the first memory die 101 or second memory die 102 on a carrier substrate 10, according to one or more embodiments. As illustrated in FIG. 2B, the semiconductor substrate 101d/102d of the respective first memory die 101 or second memory die 102d may be bonded or adhered to a carrier substrate 10. The carrier substrate 10 may be a circular wafer or a rectangular wafer. The lateral dimensions (such as the diameter of a circular wafer or a side of a rectangular wafer) of the carrier substrate 10 may be in a range from 100 mm to 500 mm, such as from 200 mm to 400 mm, although lesser and greater lateral dimensions may also be used. The carrier substrate 10 may include a semiconductor substrate, an insulating substrate, or a conductive substrate. The carrier substrate 10 may be transparent or opaque. The thickness of the carrier substrate 10 may be sufficient to provide mechanical support to an array of interposers 400 to be formed thereupon. For example, the thickness of the carrier substrate 10 may be in a range from 60 microns to 1 mm, although lesser and greater thicknesses may also be used.

An adhesive layer (not shown) may be applied to the top surface of the carrier substrate 10. In one embodiment, the carrier substrate 10 may include an optically transparent material such as glass or sapphire. In this embodiment, the adhesive layer 301 may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer (not shown) may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

FIG. 2C is a vertical cross-sectional view of the memory die stack 101/102 on the carrier substrate 10, according to one or more embodiments. As illustrated in FIG. 2C, the second memory die 102 may be inverted so as to face the first memory die 101. The second memory die 102 may then be aligned (in the z-direction) so that one or more bonding pads 102i in the second memory die 102 are aligned with the bonding pads 101i in the first memory die 101.

The second memory die 102 may then contact the first memory die 101 and bonded to the first memory die 101 using a direct bonding process. In a direct bonding process, two metal bumps (or a metal bump and a bonding pad) may be bonded together without solder disposed between the two metal bumps. For example, the direct bonding may be a copper-to-copper bonding or a gold-to-gold bonding. The methods for performing direct bonding may include thermo-compression bonding (TCB). A compressive force may be applied to press together the first memory die 101 and second memory die 102. During the bonding process, the first memory die 101 and second memory die 102 may also be heated. With the applied pressure and the elevated temperature, surface portions of the bonding pads 102i in the second memory die 102 and bonding pads 101i of the first memory die 101 may inter-diffuse, so that bonds may be formed therebetween. The heat and compression may also cause a bond to be formed between the bonding material layer 102h in the second memory die 102 and the bonding material layer 101h in the first memory die 101. After the second memory die 102 is bonded to the first memory die 101, the carrier substrate may be removed from the second memory die 102.

FIG. 2D is a vertical cross-sectional view of the oxide layer 102j formed on the memory die stack 101/102 and in contact with the semiconductor substrate 102d of the second memory die 102, according to one or more embodiments. The oxide layer 102j may include, for example, silicon oxide or other suitable oxide material for forming an oxide bond. The oxide layer 102j may be formed, for example, by chemical vapor deposition (CVD), plasma-enhanced CVD (PECVD), low pressure chemical vapor deposition (LPCVD), physical vapor deposition (PVD) or atomic layer deposition (ALD).

FIG. 2E is a vertical cross-sectional view of the oxide layer 110j on the logic die 110, according to one or more embodiments. As illustrated in FIGS. 2E, the logic die 110 may be bonded to a carrier substrate 20. The carrier substrate 20 may be similar to the carrier substrate 10 described above with respect to FIG. 2B.

In particular, an adhesive (not shown) may be applied to the carrier substrate 20. The adhesive may be similar to the adhesive used on the carrier substrate 10 and described above with respect to FIG. 2B. As illustrated in FIG. 2E, the logic die 110 may be inverted so as to face the carrier substrate 20 and pressed onto the adhesive. The adhesive may, therefore, bond the logic die 110 to the carrier substrate 20.

The oxide layer 110j may then be formed on the semiconductor substrate 110d of the logic die 110. The oxide layer 110j may include, for example, silicon oxide or other suitable oxide material for forming an oxide bond. The oxide layer 102j may be formed, for example, by chemical vapor deposition (CVD), plasma-enhanced CVD (PECVD), low pressure chemical vapor deposition (LPCVD), physical vapor deposition (PVD) or atomic layer deposition (ALD).

FIG. 2F is a vertical cross-sectional view of the logic die 110 bonded to the memory die stack 101/102, according to one or more embodiments. As illustrated in FIG. 2F, the logic die 110 may be located over the memory die stack 101/102 so that that the oxide layer 110j on the logic die 110 faces the oxide layer 102j on the second memory die 102. The logic die 110 may then be lowered onto the memory die stack 101/102 so that the oxide layer 102j contacts the oxide layer 110j.

Pressure may then be applied to the carrier wafer 10 and the carrier wafer 20 so as to form the oxide bond 1202. In particular, heat and pressure may be applied in a thermo-compression bonding (TCB) process as described above with respect to FIG. 2D. That is, a compressive force may be applied to press together the logic die 110 and memory die stack 101/102. During the bonding process, the logic die 110 and memory die stack 101/102 may also be heated. With the applied pressure and the elevated temperature, surface portions of the oxide layer 110j and oxide layer 102j may inter-diffuse, so that a bond may be formed therebetween.

FIG. 2G is a vertical cross-sectional view of the logic die 110 and memory die stack 101/102 after detaching the carrier substrate 20, according to one or more embodiments. The carrier substrate 20 may be detached, for example, by deactivating the adhesive (not shown) that bonds the carrier substrate 20 to the logic die 110. The adhesive may be deactivated, for example, by a thermal anneal at an elevated temperature. Embodiments may include an adhesive that includes a thermally-deactivated adhesive material. In other embodiments in which the carrier substrate 20 may be transparent, an adhesive may include an ultraviolet-deactivated adhesive material.

FIG. 2H is a vertical cross-sectional view of the logic die 110 and memory die stack 101/102 after forming the TSV 150, according to one or more embodiments. The forming of the TSV 150 may begin, for example, with the forming of a hole in the logic die 110 and extending across the oxide bond 1202 and into the second memory die 102. A bottom of the hole may be defined by a surface of a metal layer included in the metal interconnect structure 102g in the second memory die 102. That is, the metal layer may serve as an etch stop in the forming of the hole.

The hole may be formed, for example, by using a deep reactive-ion etching (DRIE) process. DRIE is a highly anisotropic etch process used to create deep penetration, steep-sided holes and trenches in wafer/substrates, typically with high aspect ratios. In DRIE, the substrate is placed inside a reactor, and several gases are introduced. A plasma is struck in the gas mixture which breaks the gas molecules into ions. The ions accelerated towards, and react with the surface of the material being etched, forming another gaseous efficient. This is known as the chemical part of the reactive ion etching. There is also a physical part, if ions have enough energy, they can knock atoms out of the material to be etched without chemical reaction.

The TSV 150 may then be formed in the hole, according to various embodiments. The TSV 150 may include, for example, copper or another suitable metal (e.g., silver, aluminum, chromium, nickel, tin, tungsten, titanium, gold, etc.), a copper alloy, an aluminum alloy or other suitable metal alloy. Other suitable conductive metal materials for use as the TSV 150 are within the contemplated scope of disclosure. The TSV 150 may be formed to have a thickness in a z-direction in a range from about 1 μm to about 30 μm.

The TSV 150 may be formed, for example, by forming metal material on the surface of interlayer dielectric 110f so that it fills the hole. The metal material may be formed in the hole through a deposition process or may be grown in the hole. The metal material may be deposited, for example, by chemical vapor deposition (CVD), plasma-enhanced CVD (PECVD), low pressure chemical vapor deposition (LPCVD), physical vapor deposition (PVD) (e.g., sputtering) or atomic layer deposition (ALD). A planarization step such as chemical mechanical polishing (CMP) may then be performed so as to remove the metal material from a surface of the interlayer dielectric 110f and so as to make a surface of the TSV 150 substantially coplanar with the surface of the interlayer dielectric 110f.

FIG. 2I is a vertical cross-sectional view of the logic die 110 and memory die stack 101/102 after forming the connecting structure 115, according to one or more embodiments. The connecting structure 115 may be formed by first forming the one or more metal layers 115g on the interlayer dielectric 110f. The metal layers 115g may be formed, for example, by forming a patterned photoresist layer on the surface of the interlayer dielectric 110f, depositing a metal material in the openings of the patterned photoresist layer, and then removing the photoresist layer so. The metal material may be deposited, for example, by CVD, PECVD, LPCVD, PVD (e.g., sputtering), ALD, or other suitable deposition method. The dielectric layer 115f (e.g., SiO₂) may be deposited on the metal layers 115g, for example, by CVD, PECVD, LPCVD, PVD (e.g., sputtering), ALD, or other suitable deposition method. The metal layers 115g and dielectric layer 115f may then be planarized, for example, by CMP.

The bonding material layer 115h (e.g., silicon oxide or binding polymers, such as an epoxy, a polyimide (PI), a benzocyclobutene (BCB), and a polybenzoxazole (PBO), or other suitable bonding layer material) may be deposited on the metal layers 115g and dielectric layer 115f by CVD, PECVD, LPCVD, PVD (e.g., sputtering), ALD, or other suitable deposition method. Holes may then be formed in the bonding material layer 115h by a photolithographic process. Metal material may then be deposited (by CVD, PECVD, LPCVD, PVD (e.g., sputtering), ALD, or other suitable deposition method) so as to form the bonding pads 115i the holes. The bonding pads 115i and bonding material layer 115h may then be planarized, for example, by CMP to complete the formation of the connecting structure 115, and complete the formation of the first chiplet 100.

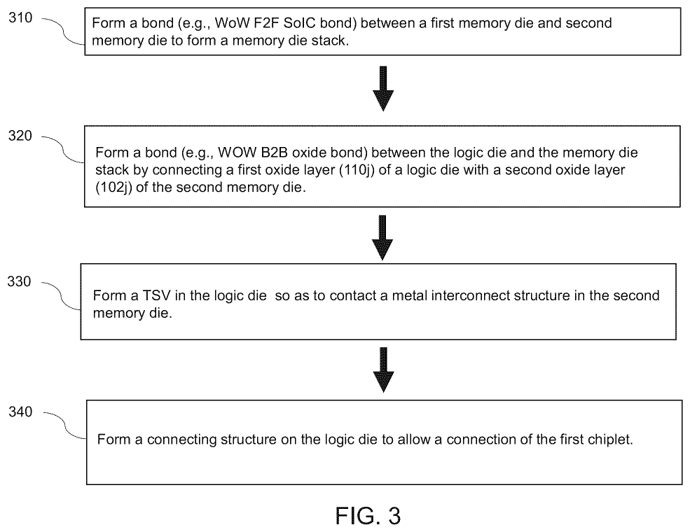

FIG. 3 is a flow chart illustrating a method of forming a first chiplet 100, according to various embodiments. The method includes Step 310 of forming a direct bond (e.g., WoW F2F SoIC bond) between a first memory die and second memory die to form a memory die stack, a Step 320 of forming a bond (e.g., WOW B2B oxide bond) between the logic die and the memory die stack, a Step 330 of forming a TSV in the logic die so as to contact a metal interconnect structure in the second memory die, and a Step 340 of forming a connecting structure on the logic die to allow a connection of the first chiplet.

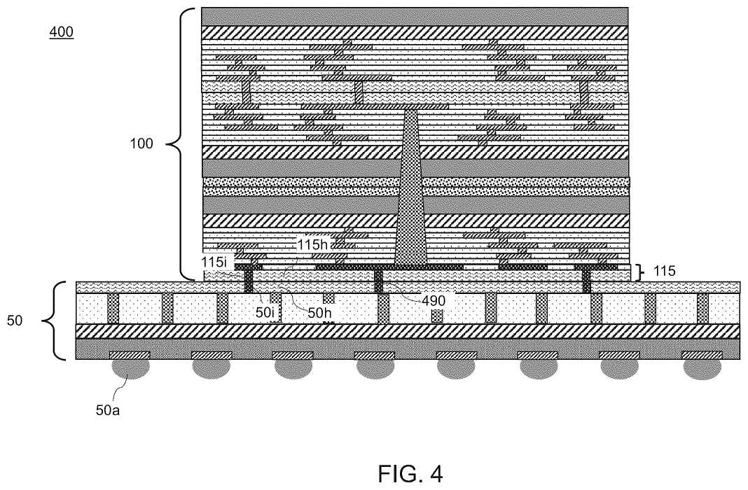

FIG. 4 is a vertical cross-sectional view of semiconductor device 400 including the first chiplet 100, according to one or more embodiments. As illustrated in FIG. 4, semiconductor device 400 may include a base die chiplet 50, and the first chiplet 100 (e.g., a chip-on-wafer (CoW) of the first chiplet 100) bonded to the base die chiplet 50. The first chiplet 100 (e.g., top die chiplet) may be WoW stacked memory and logic tiers, and may work as a co-processor, accelerator, or on-chip memory buffer for the base die chiplet 50. The base die chiplet 50 may be a versatile CPU, GPU, FPGA, networking chip, AI DNN accelerator, etc.

In particular, the first chiplet 100 may be inverted so that the connecting structure 115 faces the base die chiplet 50. The first chiplet 100 may be bonded by a direct bond (e.g., hybrid bond) to the base die chiplet 50 so that that bonding material layer 115h of the first chiplet 100 is bonded to a bonding material layer 50h of the base die chiplet 50, and the bonding pad 115i of the first chiplet 100 is bonded to a bonding pad 50i of the base die chiplet 50 to form a bonding pad interconnect 490. One or more solder balls 50a (e.g., a ball grid array (BGA)) may be formed on a side of the base die chiplet 50 that is opposite the first chiplet 100, which may allow the semiconductor device 400 to be mounted to a substrate such as a packaging substrate (e.g., printed circuit board (PCB)).

The semiconductor device 400 may provide a low power and high memory capacity CIM chiplet architecture that may be achieved with direct-bonded and oxide-bonded WoW tiers. The first chiplet 100 may include, for example, an integrated CMOS-compatible volatile memory and non-volatile memory to achieve desired synaptic properties for analog CIM and digital CIM/CNM architectures. The CIM/CNM chiplet architectures of the first chiplet 100 may be further integrated into the base die chiplet 50. The base die chiplet 50 may include, for example, one or more of CPUs, GPUs, FPGAs, and/or network chips. Thus, the semiconductor device 400 may enhance an overall computing force and to enable multiple accelerating dataflow and functionality of artificial intelligence/deep neural network (AI/DNN) chips.

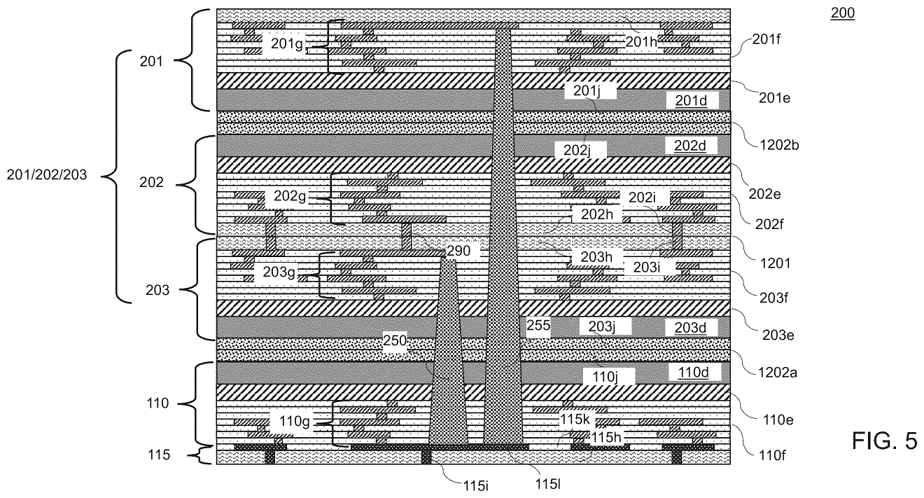

FIG. 5 is a vertical cross-sectional view of a second chiplet 200 (e.g., a 3D chiplet, top chiplet, etc.) according to one or more embodiments. The second chiplet 200 may include the logic die 110 and a memory die stack 201/202/203 stacked on the logic die 110. The memory die stack 201/202/203 may include a first memory die 201, a second memory die 202 and a third memory die 203.

The first memory die 201 may include a semiconductor substrate 201d, an active region 201e (including one or more memory circuits) on the semiconductor substrate 201d, an interlayer dielectric 201f on the active region 201e, one or more metal interconnect structures 201g in the interlayer dielectric 201f, and a bonding material layer 201h on the interlayer dielectric 201f.

The second memory die 202 may be inverted (so as to face the logic die 110) and include a semiconductor substrate 202d, an active region 202e (including one or more memory circuits) on the semiconductor substrate 202d, an interlayer dielectric 202f on the active region 202e, one or more metal interconnect structures 202g in the interlayer dielectric 202f, a bonding material layer 202h on the interlayer dielectric 202f, and one or more bonding pads 202i in the bonding material layer 202h.

The third memory die 203 may include a semiconductor substrate 203d, an active region 203e (including one or more memory circuits) on the semiconductor substrate 203d, an interlayer dielectric 203f on the active region 203e, one or more metal interconnect structures 203g in the interlayer dielectric 203f, a bonding material layer 203h on the interlayer dielectric 203f, and one or more bonding pads 203i in the bonding material layer 203h.

In the memory die stack 201/202/203, the first memory die 201 may be bonded (e.g., WoW B2B bonded) to the second memory die 202 by an oxide bond 1202b (second oxide bond) between an oxide layer 201j on the first memory die 201 and an oxide layer 202j on the second memory die 202. The second memory die 202 may be bonded (e.g., WoW F2F bonded) to the third memory die 203 by a direct bond 1201 (e.g., hybrid bond). In the direct bond 1201, the bonding material layer 202h of the second memory die 202 may be direct bonded to the bonding material layer 203h of the third memory die 203, and the bonding pads 202i may be bonded to the bonding pads 203i to form a bonding pad interconnect 290. The memory die stack 201/202/203 may be bonded (e.g., WoW B2B bonded) to the logic die 110 by an oxide bond 1202a (first oxide bond) between an oxide layer 203j on the third memory die 203 and the oxide layer 110j on the logic die 110.

The second chiplet 200 may also include a first TSV 250 and second TSV 255 that may provide an electrical connection within the second chiplet 200. The first TSV 250 and second TSV 255 may be the only TSVs in the second chiplet 200. That is, prior to the assembly of the second chiplet 200, the TSVs are absent from the first memory die 201, second memory die 202, third memory die 203 and logic die 110.

The first TSV 250 may be located in the logic die 110 and extend across the oxide bond 1202a into the third memory die 203. The first TSV 250 may have a thickness in a z-direction in a range from about 1 μm to about 30 μm, but may vary depending on the thickness of the logic die 110 and third memory die 203.

The first TSV 250 may contact a metal layer (e.g., metal trace) in the metal interconnect structure 203g which is connected to the active region 203e of the third memory die 203. Thus, data may be transmitted to and from the active region 203e by the first TSV 250. In addition, the metal interconnect structure 203g may be connected across the direct bond 1201 to the metal interconnect structure 202g in the second memory die 201 by a connection (bonding pad interconnect 290) between one or more bonding pads 202i and one or more bonding pads 203i. Thus, data may be transmitted to and from the active region 202e in the second memory die 202 by the first TSV 250. That is, the first TSV 250 may provide a data link between the second memory die 202 and the logic die 110, and between the third memory die 203 and the logic die 110.

The second TSV 255 may be located in the logic die 110 and extend across the oxide bond 1202a, the direct bond 1201 and the oxide bond 1202b into the first memory die 201. The second TSV 255 may have a thickness in a z-direction in a range from about 10 μm to about 50 μm, but may vary depending on the thickness of the logic die 110, third memory die 203, the second memory die 202 and the first memory die 201.

The second TSV 255 may contact a metal layer (e.g., metal trace) in the metal interconnect structure 201g which is connected to the active region 201e of the first memory die 201. Thus, data may be transmitted to and from the active region 201e by the second TSV 255. That is, the second TSV 255 may provide a data link between the first memory die 201 and the logic die 110. Thus, by the first TSV 250 and second TSV 255, the current sum data paths for the first memory die 201, second memory die 202 and third memory die 203 may be combined at the logic die 110.

The second chiplet 200 may also include the connecting structure 115 on the logic die 110. The connecting structure 115 may include a back end of line (BEOL) layer to connect the first TSV 250 and the second TSV 255 with a logic circuit in the logic die 110. In particular, the metal layers 115g of the connecting structure 115 may be connected to the metal interconnect structure 110g in the logic die 110 and connected to the first TSV 250 and second TSV 255. Thus, data may be transmitted to and from the logic region 110e by the first TSV 250 and second TSV 255.

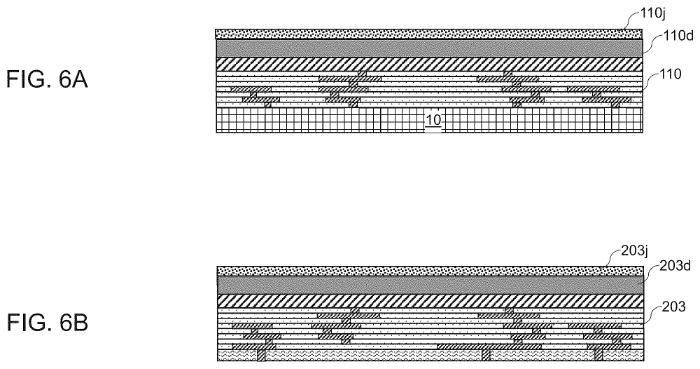

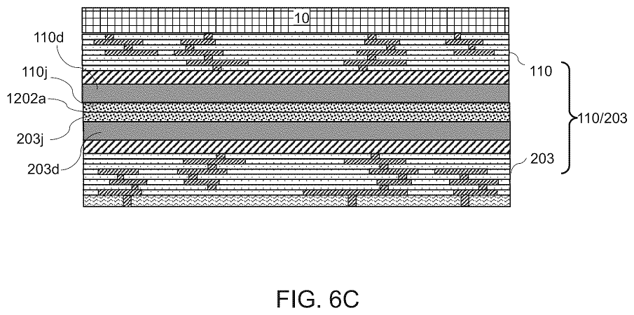

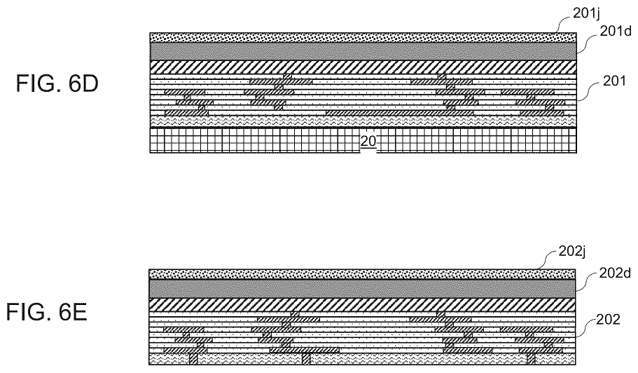

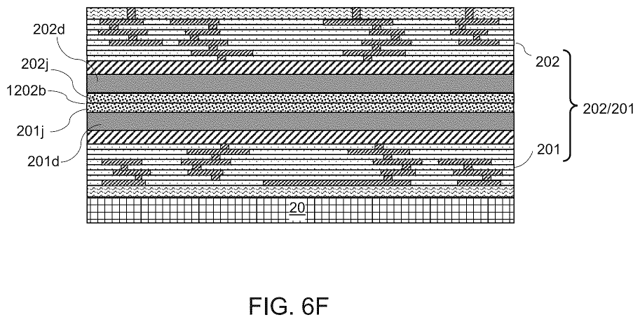

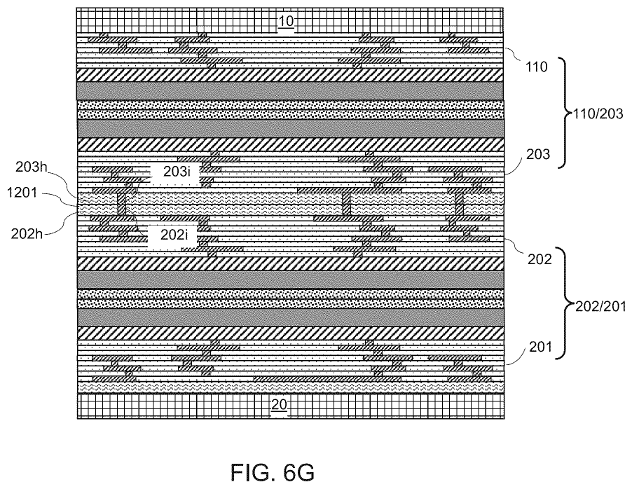

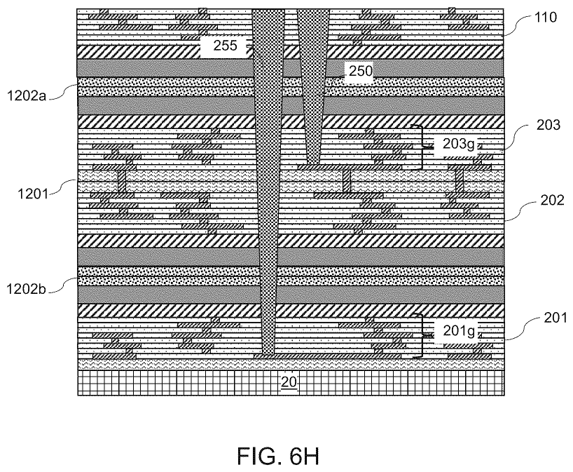

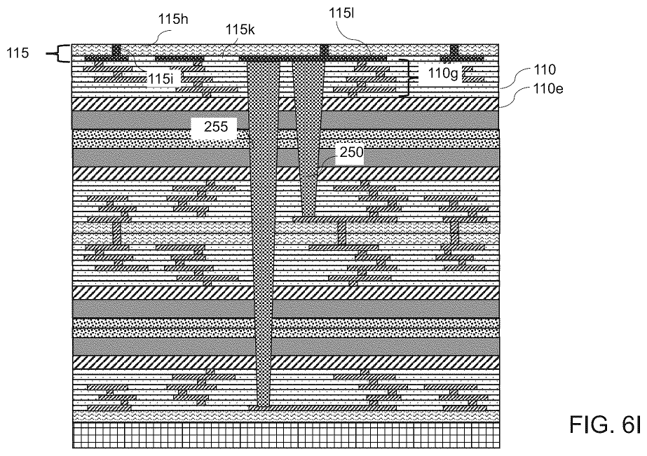

FIGS. 6A-6I are vertical cross-sectional views of various intermediate structures in a method of forming the second chiplet 200, according to one or more embodiments. In particular, FIG. 6A is a vertical cross-sectional view of the logic die 110 after forming the oxide layer 110j, according to one or more embodiments. The logic die 110 may be inverted and the face of the logic die 110 may be bonded to a carrier substrate 10. The oxide layer 110j may then be formed on the semiconductor substrate 110d.

FIG. 6B is a vertical cross-sectional view of the third memory die 203 after forming the oxide layer 203j over the substrate 203d, according to one or more embodiments. As illustrated in FIG. 6B, the third memory die 203 may be inverted and the oxide layer 203j may be formed on the semiconductor substrate 203d.

FIG. 6C is a vertical cross-sectional view of a die stack 110/203, according to one or more embodiments. As illustrated in FIG. 6C, the logic die 110 may be bonded to the third memory die 203 to form the die stack 110/203. In particular, the logic die 110 may be located over the third memory die 203 so that the oxide layer 110j on the semiconductor substrate 110d may face the oxide layer 203j on the semiconductor substrate 203d. Pressure and heat may then be applied on order to form the oxide bond 1202a (e.g., thermo-compression bond) between the logic die 110 and the third memory die 203.

FIG. 6D is a vertical cross-sectional view of the first memory die 201 after forming the oxide layer 201j, according to one or more embodiments. The first memory die 201 may be inverted and the face of the first memory die 201 may be bonded to a carrier substrate 20. The oxide layer 201j may then be formed on the semiconductor substrate 201d.

FIG. 6E is a vertical cross-sectional view of the second memory die 202 after forming the oxide layer 202j, according to one or more embodiments. As illustrated in FIG. 6E, the second memory die 202 may be inverted and the oxide layer 202j may be formed on the semiconductor substrate 202d.

FIG. 6F is a vertical cross-sectional view of a memory die stack 202/201, according to one or more embodiments. As illustrated in FIG. 6F, the second memory die 202 may be bonded to the first memory die 201 to form the memory die stack 202/201. In particular, the second memory die 202 may be located over the first memory die 201 so that the oxide layer 202j on the semiconductor substrate 202d may face the oxide layer 201j on the semiconductor substrate 201d. Pressure and heat may then be applied on order to form the oxide bond 1202b (e.g., thermo-compression bond) between the second memory die 202 and the first memory die 201.

FIG. 6G is a vertical cross-sectional view of an intermediate structure after forming a direct bond 1201, according to one or more embodiments. As illustrated in FIG. 6G, the die stack 110/203 may be bonded by a direct bonding process (e.g., thermocompression bonding) to the memory die stack 202/201. In particular, the bonding pads 202i of the second memory die 202 may be bonded to the bonding pads 203i of the third memory die 203 (to form a bonding pad interconnect 290), and the bonding material layer 202h in the second memory die 202 may be bonded to the bonding material layer 203h in the third memory die 203.

FIG. 6H is a vertical cross-sectional view of an intermediate structure after forming the first TSV 250 and second TSV 255, according to one or more embodiments. As illustrated in FIG. 6H, the carrier substrate 10 may be detached from the logic die 110. Then the first TSV 250 and second TSV 255 may be formed in the intermediate structure by a process similar to the process described above for the TSV 150. In particular, the first TSV 250 may be formed so as to extend across the oxide bond 1202a and contact a metal layer in the metal interconnect structure 203g in the third memory die 203. The second TSV 255 may be formed so as to extend across the oxide bond 1202a, the direct bond 1201, and the oxide bond 1202b, and contact a metal layer in the metal interconnect structure 201g in the first memory die 201.

FIG. 6I is a vertical cross-sectional view of the intermediate structure after forming the connecting structure 115, according to one or more embodiments. The connecting structure 115 may be formed so that one or more metal layers 115g of the connecting structure 115 may contact the first TSV 250 and the second TSV 255, and contact the metal interconnect structure 110g in the logic die 110. The first TSV 250 and the second TSV 255 may thereby be electrically coupled to the active region 110e of the logic die 110.

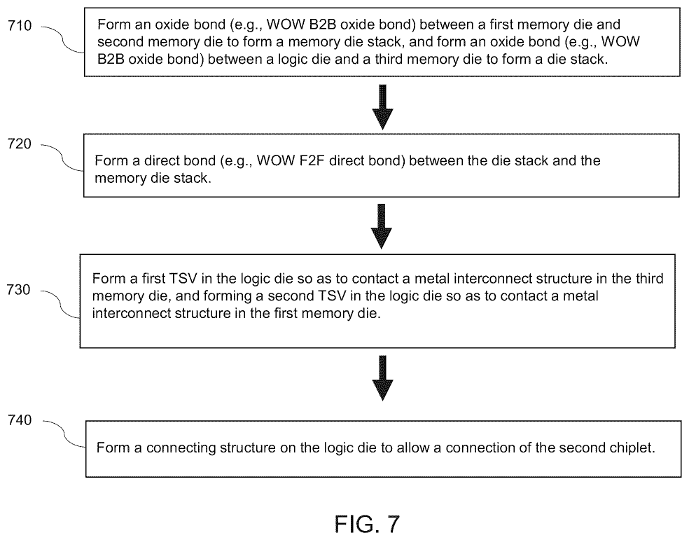

FIG. 7 is a flow chart illustrating a method of forming a second chiplet 200, according to various embodiments. The method includes Step 710 of forming an oxide bond (e.g., WOW B2B oxide bond) between a first memory die and second memory die to form a memory die stack, and forming an oxide bond (e.g., WOW B2B oxide bond) between a logic die and a third memory die to form a die stack. The method further includes a Step 720 of forming a direct bond (e.g., WOW F2F direct bond) between the die stack and the memory die stack. The method further includes a Step 730 of forming a first TSV in the logic die so as to contact a metal interconnect structure in the third memory die, and forming a second TSV in the logic die so as to contact a metal interconnect structure in the first memory die, and a Step 740 of forming a connecting structure on the logic die to allow a connection of the second chiplet.

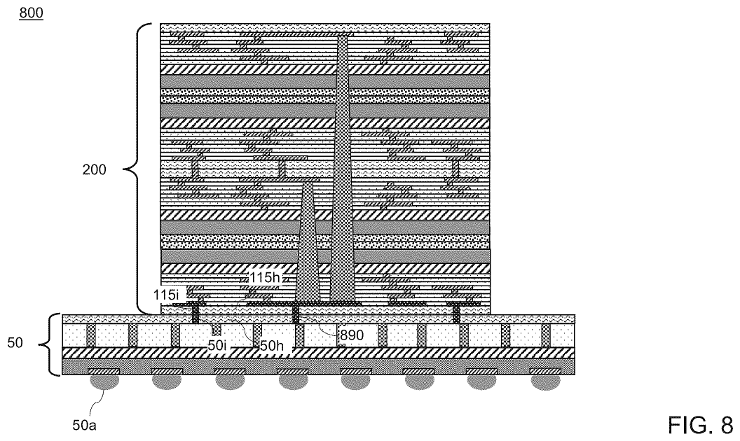

FIG. 8 is a vertical cross-sectional view of semiconductor device 800 including the second chiplet 200, according to one or more embodiments. As illustrated in FIG. 8, the semiconductor device 800 may include a base die chiplet 50, and the second chiplet 200 (e.g., a chip-on-wafer (CoW) of the second chiplet 200) bonded to the base die chiplet 50. The second chiplet 200 (e.g., top die chiplet) can be WoW stacked memory and logic tiers, and may work as a co-processor, accelerator, or on-chip memory buffer for the base die chiplet 50. The base die chiplet 50 can be a versatile CPU, GPU, FPGA, networking chip, AI DNN accelerator, etc.

In particular, the second chiplet 200 may be inverted so that the connecting structure 115 faces the base die chiplet 50. The second chiplet 200 may be bonded by a direct bond (e.g., hybrid bond) to the base die chiplet 50 so that that bonding material layer 115h of the second chiplet 200 is bonded to a bonding material layer 50h of the base die chiplet 50, and the bonding pad 115i of the second chiplet 200 is bonded to a bonding pad 50i of the base die chiplet 50 to form a bonding pad interconnect 890. One or more solder balls 50a (e.g., a ball grid array (BGA)) may be formed on a side of the base die chiplet 50 that is opposite the first chiplet 100, which may allow the semiconductor device 800 to be mounted to a substrate such as a packaging substrate.

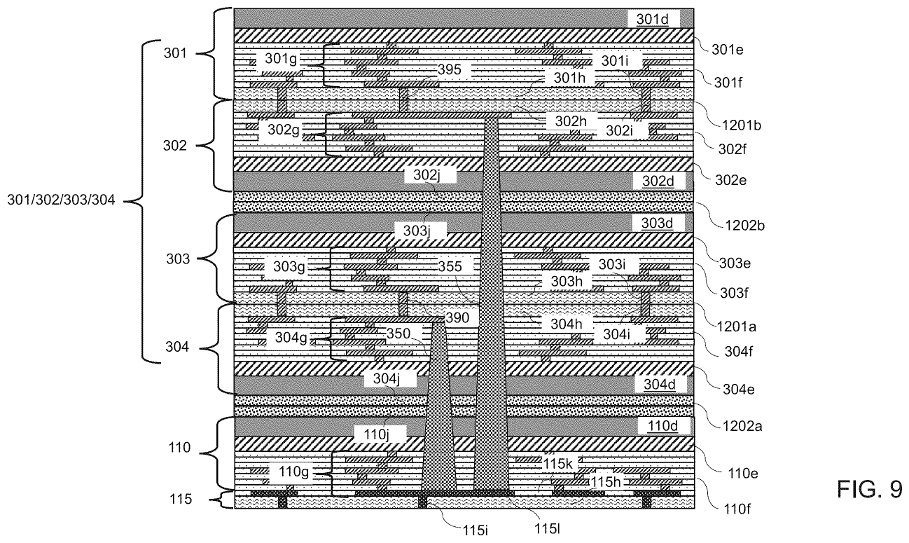

FIG. 9 is a vertical cross-sectional view of a third chiplet 300 (e.g., a 3D chiplet, top chiplet, etc.) according to one or more embodiments. The third chiplet 300 may include the logic die 110 and a memory die stack 301/302/303/304 stacked on the logic die 110. The memory die stack 301/303/303/304 may include a first memory die 301, a second memory die 302, a third memory die 303 and a fourth memory die 304.

The first memory die 301 may be inverted (so as to face the logic die 110) and include a semiconductor substrate 301d, an active region 301e (including one or more memory circuits) on the semiconductor substrate 301d, an interlayer dielectric 301f on the active region 301e, one or more metal interconnect structures 301g in the interlayer dielectric 301f, a bonding material layer 301h on the interlayer dielectric 301f, and one or more bonding pads 302i in the bonding material layer 301h.

The second memory die 302 may include a semiconductor substrate 302d, an active region 302e (including one or more memory circuits) on the semiconductor substrate 302d, an interlayer dielectric 302f on the active region 302e, one or more metal interconnect structures 302g in the interlayer dielectric 302f, a bonding material layer 302h on the interlayer dielectric 302f, and one or more bonding pads 302i in the bonding material layer 302h.

The third memory die 303 may be inverted (so as to face the logic die 110) and include a semiconductor substrate 303d, an active region 303e (including one or more memory circuits) on the semiconductor substrate 303d, an interlayer dielectric 303f on the active region 303e, one or more metal interconnect structures 303g in the interlayer dielectric 303f, a bonding material layer 303h on the interlayer dielectric 303f, and one or more bonding pads 303i in the bonding material layer 303h.

The fourth memory die 304 may include a semiconductor substrate 304d, an active region 304e (including one or more memory circuits) on the semiconductor substrate 304d, an interlayer dielectric 304f on the active region 304e, one or more metal interconnect structures 304g in the interlayer dielectric 304f, a bonding material layer 304h on the interlayer dielectric 304f, and one or more bonding pads 304i in the bonding material layer 304h.

In the memory die stack 301/302/303/304, the first memory die 301 may be direct bonded (e.g., WoW F2F bonded) to the second memory die 302 by a direct bond 1201b (e.g., hybrid bond). In the direct bond 1201b, the bonding material layer 301h on the first memory die 301 may be direct bonded to the bonding material layer 302h on the second memory die 302, and the bonding pads 301i may be direct bonded to the bonding pads 302i (to form a bonding pad interconnect 395). The second memory die 302 may be bonded (e.g., WoW B2B bonded) to the third memory die 303 by an oxide bond 1202b between an oxide layer 302j on the second memory die 303 and the oxide layer 303j on the third memory die 303. The third memory die 303 may be direct bonded (e.g., WoW F2F bonded) to the fourth memory die 304 by a direct bond 1201a (e.g., hybrid bond). In the direct bond 1201a, the bonding material layer 303h on the third memory die 303 may be direct bonded to the bonding material layer 304h on the fourth memory die 304, and the bonding pads 303i may be direct bonded to the bonding pads 304i (to form a bonding pad interconnect 390). The memory die stack 301/302/303/304 may be bonded (e.g., WoW B2B bonded) to the logic die 110 by an oxide bond 1202a between an oxide layer 304j on the fourth memory die 304 and the oxide layer 110j on the logic die 110.

The third chiplet 300 may also include a first TSV 350 and a second TSV 355 that may provide an electrical connection within the third chiplet 300. The first TSV 350 and second TSV 355 may be the only TSVs in the third chiplet 300. That is, prior to the assembly of the third chiplet 300, there may be no TSVs in the first memory die 301, second memory die 302, third memory die 303, fourth memory die 304 or logic die 110.

The first TSV 350 may be located in the logic die 110 and extend across the oxide bond 1202a into the fourth memory die 304. The first TSV 350 may have a thickness in a z-direction in a range from about 1 μm to about 30 μm, depending on the thicknesses of the various dies that it may pass through.

The first TSV 350 may contact a metal layer (e.g., metal trace) in the metal interconnect structure 304g which is connected to the active region 304e of the fourth memory die 304. Thus, data may be transmitted to and from the active region 304e by the first TSV 350. In addition, the metal interconnect structure 304g may be connected across the direct bond 1201a to the metal interconnect structure 303g in the third memory die 303 by a connection between one or more bonding pads 304i and one or more bonding pads 303i. Thus, data may be transmitted to and from the active region 303e in the third memory die 303 by the first TSV 350. That is, the first TSV 350 may provide a data link between the third memory die 303 and the logic die 110, and between the fourth memory die 304 and the logic die 110.

The second TSV 355 may be located in the logic die 110 and extend across the oxide bond 1202a, the direct bond 1201a and the oxide bond 1202b into the second memory die 302. The second TSV 355 may have a thickness in a z-direction in a range from about 10 μm to about 50 μm, depending on the thicknesses of the various dies that it may pass through.

The second TSV 355 may contact a metal layer (e.g., metal trace) in the metal interconnect structure 302g which is connected to the active region 302e of the second memory die 302. Thus, data may be transmitted to and from the active region 302e by the second TSV 355. In addition, the metal interconnect structure 302g may be connected across the direct bond 1201b (second direct bond) to the metal interconnect structure 301g in the first memory die 301 by a connection (bonding pad interconnect 395) between one or more bonding pads 302i and one or more bonding pads 301i. Thus, data may be transmitted to and from the active region 301e in the first memory die 301 by the second TSV 355. That is, the second TSV 355 may provide a data link between the first memory die 301 and the logic die 110, and between the second memory die 302 and the logic die 110.

The third chiplet 300 may also include the connecting structure 115 on the logic die 110. The connecting structure 115 may include a back end of line (BEOL) layer to connect the first TSV 350 and the second TSV 355 with a logic circuit in the logic die 110. In particular, the metal layers 115g of the connecting structure 115 may be connected to the metal interconnect structure 110g in the logic die 110 and connected to the first TSV 350 and second TSV 355. Thus, data may be transmitted to and from the logic region 110e by the first TSV 350 and second TSV 355.

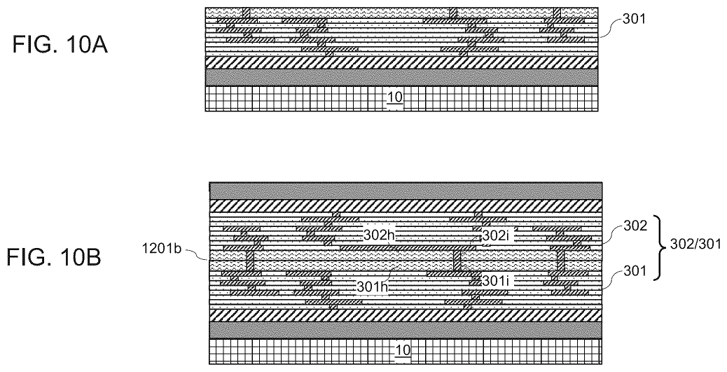

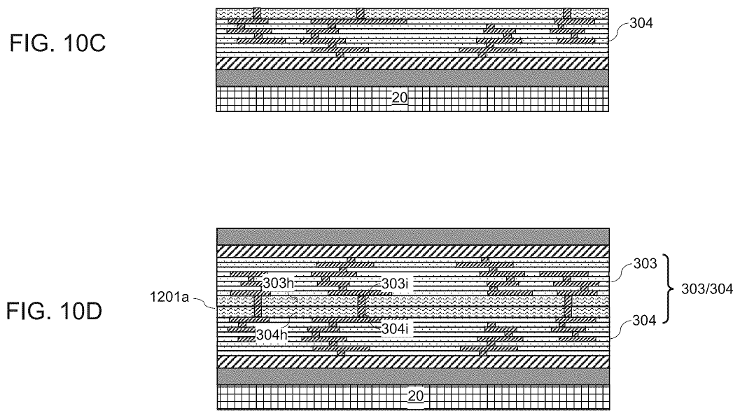

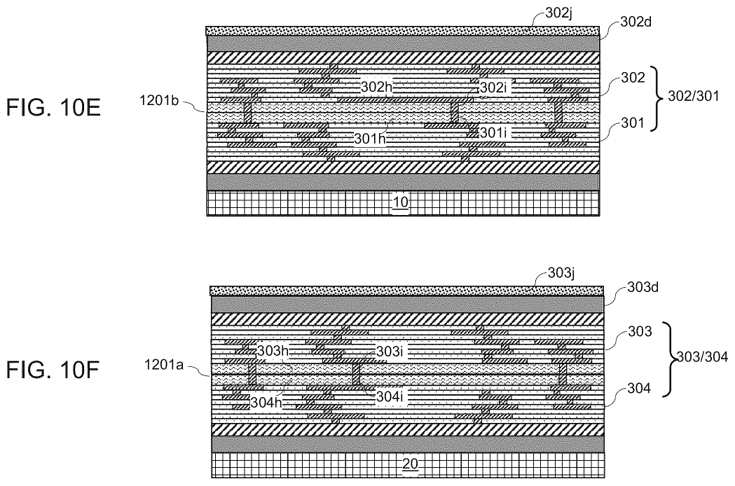

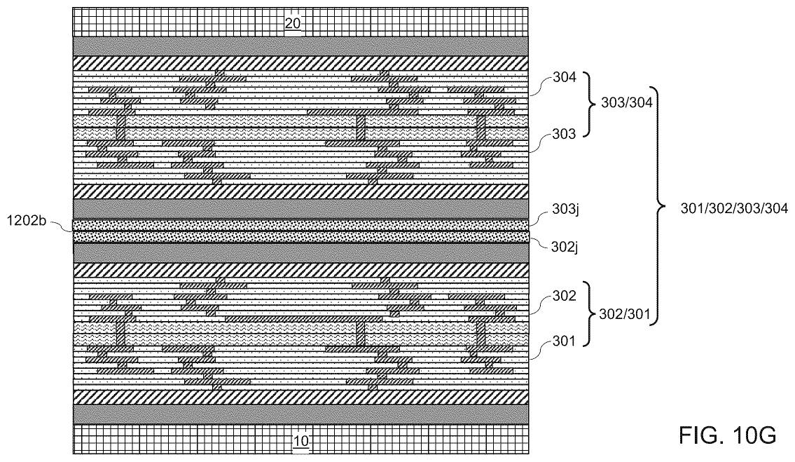

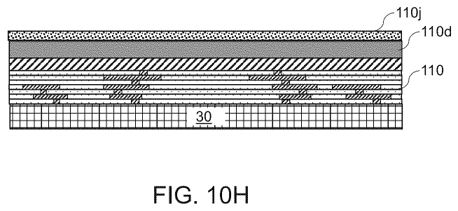

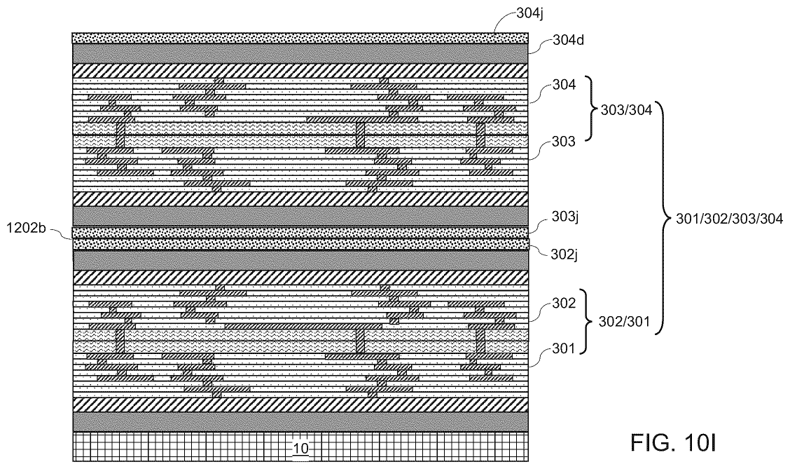

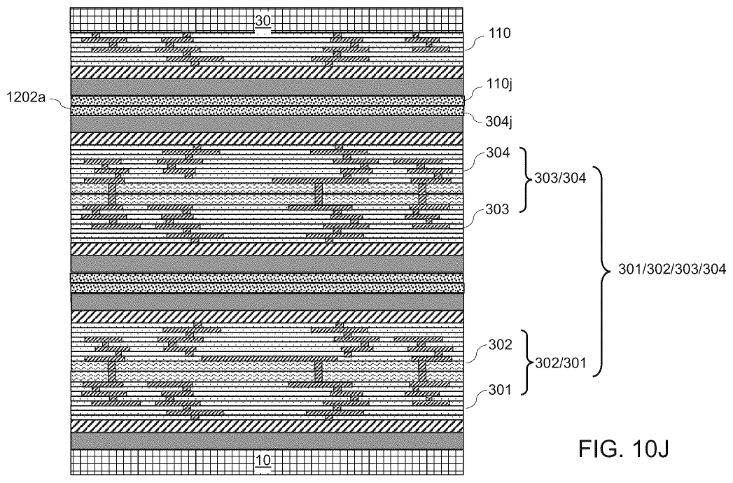

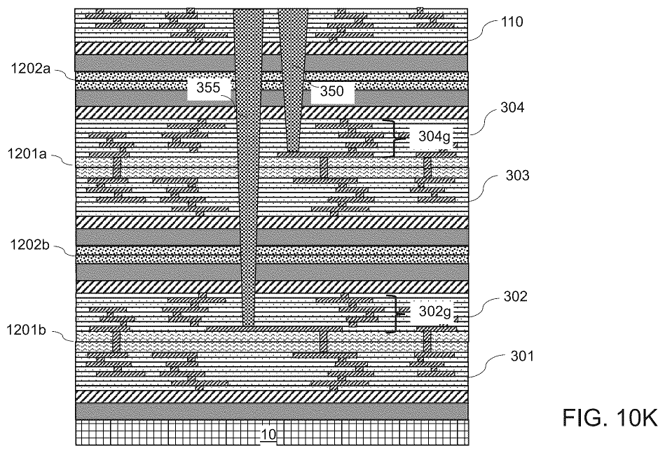

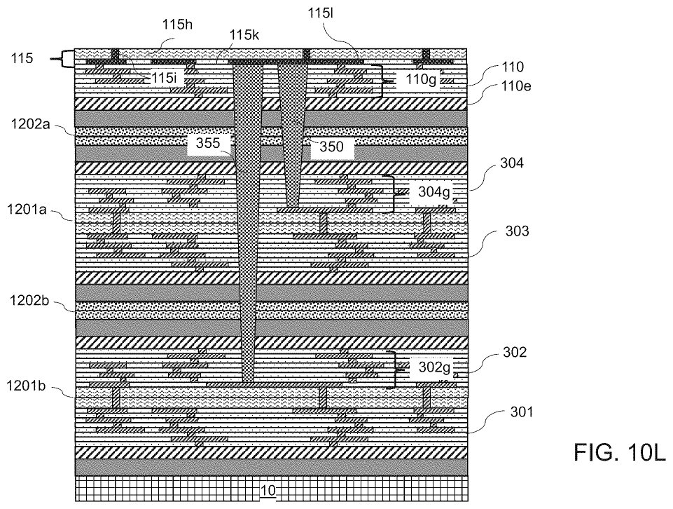

FIGS. 10A-10I are vertical cross-sectional views of various intermediate structures in a method of forming the third chiplet 300, according to one or more embodiments. In particular, FIG. 10A is a vertical cross-sectional view of the first memory die 301, according to one or more embodiments. As illustrated in FIG. 10A, the first memory die 301 may be bonded to a carrier substrate 10.

FIG. 10B is a vertical cross-sectional view of a memory die stack 302/301 (first memory die stack), according to one or more embodiments. As illustrated in FIG. the second memory die 301 may be bonded to the first memory die 301 to form the memory die stack 302/301. In particular, the second memory die 302 may be inverted so as to face the first memory die 301, and positioned over the first memory die 301. The second memory die 302 may be aligned in the z-direction with the first memory die 301 so that the bonding pads 302i in the bonding material layer 302h are aligned with the bonding pads 301i in the bonding material layer 301h. The second memory die 302 may then be lowered onto the first memory die 301. Pressure and heat may then be applied on order to form the direct bond 1201b (e.g., thermo-compression bond) so that the bonding pads 302i are bonded to the bonding pads 301i (to form a bonding pad interconnect 395), and the bonding material layer 302h is bonded to the bonding material layer 301h.

FIG. 10C is a vertical cross-sectional view of the fourth memory die 304, according to one or more embodiments. As illustrated in FIG. 10C, the fourth memory die 304 may be bonded to a carrier substrate 20.

FIG. 10D is a vertical cross-sectional view of a memory die stack 303/304 (second memory die stack), according to one or more embodiments. As illustrated in FIG. 10D, the third memory die 303 may be bonded to the fourth memory die 304 to form the memory die stack 303/304. In particular, the third memory die 303 may be inverted so as to face the fourth memory die 304, and positioned over the fourth memory die 304. The third memory die 303 may be aligned in the z-direction with the fourth memory die 304 so that the bonding pads 303i in the bonding material layer 303h are aligned with the bonding pads 304i in the bonding material layer 304h. The third memory die 303 may then be lowered onto the fourth memory die 304. Pressure and heat may then be applied on order to form the direct bond 1201a (e.g., thermo-compression bond) so that the bonding pads 303i are bonded to the bonding pads 304i (to form a bonding pad interconnect 390), and the bonding material layer 303h is bonded to the bonding material layer 303h.

FIG. 10E is a vertical cross-sectional view of a memory die stack 302/301, according to one or more embodiments. In particular, FIG. 10E is a vertical cross-sectional view of the memory die stack 302/301 after forming the oxide layer 302j, according to one or more embodiments. In particular, the oxide layer 302j may be formed on the semiconductor substrate 302d of the second memory die 302.

FIG. 10F is a vertical cross-sectional view of the memory die stack 303/304 after forming the oxide layer 303j, according to one or more embodiments. In particular, the oxide layer 303j may be formed on the semiconductor substrate 303d of the third memory die 303.

FIG. 10G is a vertical cross-sectional view of an intermediate structure after forming the oxide bond 1202b, according to one or more embodiments. As illustrated in FIG. 10G, the memory die stack 303/304 may be inverted and positioned over the memory die stack 302/301, so that the oxide layer 303j faces the oxide layer 302j. The memory die stack 303/304 may then be lowered onto the memory die stack 302/301 so that the oxide layer 303j contacts the oxide layer 302j. Pressure and heat may then be applied to the memory die stack 303/304 and the memory die stack 302/301 (e.g., in a thermocompression bonding process) so that the oxide layer 303j is bonded the oxide layer 302j by the oxide bond 1202b, to form the memory die stack 301/302/303/304 (third memory die stack).

FIG. 10H is a vertical cross-sectional view of the logic die 110 after forming the oxide layer 110j, according to one or more embodiments. The logic die 110 may be inverted and the face of the logic die 110 may be bonded to a carrier substrate 30. The oxide layer 110j may then be formed on the semiconductor substrate 110d.

FIG. 10I is a vertical cross-sectional view of an intermediate structure after he forming of the oxide layer 303j, according to one or more embodiments. As illustrated in FIG. 10H, the carrier substrate 20 has been detached from the intermediate structure in FIG. 10G to expose a surface of the semiconductor substrate 304d. The oxide layer 304j may then be formed on the surface of the semiconductor substrate 304d.

FIG. 10J is a vertical cross-sectional view of an intermediate structure after forming the oxide bond 1202a, according to one or more embodiments. As illustrated in FIG. 10J, the logic die 110 may be positioned over the memory die stack 301/302/303/304, so that the oxide layer 110j faces the oxide layer 304j. The logic die 110 may then be lowered onto the memory die stack 301/302/303/304 so that the oxide layer 303j contacts the oxide layer 302j. Pressure and heat may then be applied to the logic die 110 and the memory die stack 301/302/303/304 (e.g., in a thermocompression bonding process) so that the oxide layer 110j is bonded the oxide layer 304j by the oxide bond 1202a.

FIG. 10K is a vertical cross-sectional view of an intermediate structure after forming the first TSV 350 and second TSV 355, according to one or more embodiments. As illustrated in FIG. 10K, the carrier substrate 20 may be detached from the logic die 110. Then, the first TSV 350 and second TSV 355 may be formed in the intermediate structure by a process similar to the process described above for the TSV 150. In particular, the first TSV 350 may be formed so as to extend across the oxide bond 1202a and contact a metal layer in the metal interconnect structure 304g in the fourth memory die 304. The second TSV 355 may be formed so as to extend across the oxide bond 1202a, the direct bond 1201a, and the oxide bond 1202b, and contact a metal layer in the metal interconnect structure 302g in the second memory die 302.

FIG. 10L is a vertical cross-sectional view of the intermediate structure after forming the connecting structure 115, according to one or more embodiments. The connecting structure 115 may be formed so that one or more metal layers 115g of the connecting structure 115 may contact the first TSV 350 and the second TSV 355, and contact the metal interconnect structure 110g in the logic die 110. The first TSV 350 and the second TSV 355 may thereby be electrically coupled to the active region 110e of the logic die 110. This may complete the formation of third chiplet 300.

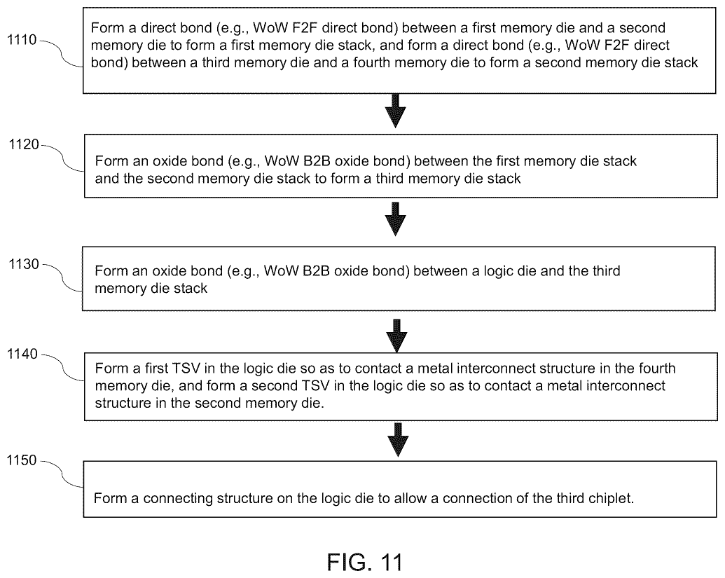

FIG. 11 is a flow chart illustrating a method of forming a third chiplet 300, according to various embodiments. The method includes a Step 1110 of forming a direct bond (e.g., WoW F2F direct bond) between a first memory die and a second memory die to form a first memory die stack, and forming a direct bond (e.g., WoW F2F direct bond) between a third memory die and a fourth memory die to form a second memory die stack, a Step 1120 of forming an oxide bond (e.g., WoW B2B oxide bond) between the first memory die stack and the second memory die stack to form a third memory die stack, a Step 1130 of forming an oxide bond (e.g., WoW B2B oxide bond) between a logic die and the third memory die stack, a Step 1140 of forming a first TSV in the logic die so as to contact a metal interconnect structure in the fourth memory die, and forming a second TSV in the logic die so as to contact a metal interconnect structure in the second memory die, and a Step 1150 of forming a connecting structure on the logic die to allow a connection of the third chiplet.

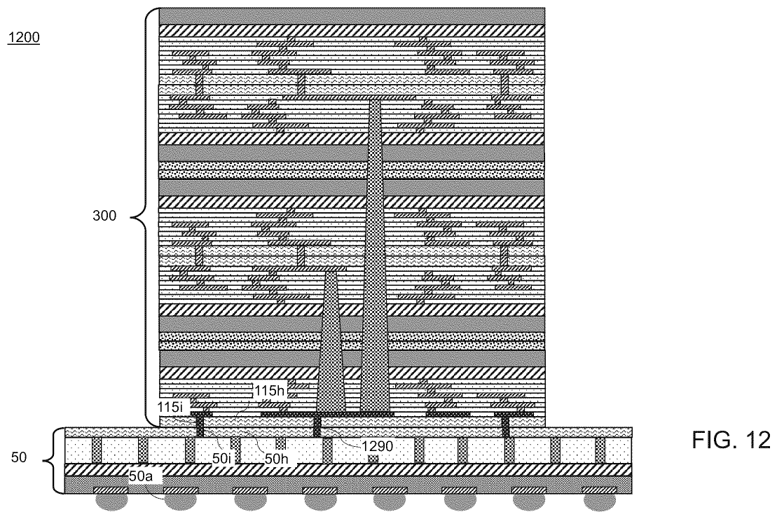

FIG. 12 is a vertical cross-sectional view of semiconductor device 1200 including the third chiplet 300, according to one or more embodiments. As illustrated in FIG. 12, semiconductor device 1200 may include the base die chiplet 50, and the third chiplet 300 (e.g., a chip-on-wafer (CoW) of the third chiplet 300) bonded to the base die chiplet 50. The third chiplet 300 (e.g., top die chiplet) can be WoW stacked memory and logic tiers, and may work as a co-processor, accelerator, or on-chip memory buffer for the base die chiplet 50.

In particular, the third chiplet 300 may be inverted so that the connecting structure 115 faces the base die chiplet 50. The third chiplet 300 may be bonded by a direct bond (e.g., hybrid bond) to the base die chiplet 50 so that that bonding material layer 115h of the third chiplet 300 is bonded to a bonding material layer 50h of the base die chiplet 50, and the bonding pad 115i of the third chiplet 300 is bonded to a bonding pad 50i of the base die chiplet 50 to form a bonding pad interconnect 1290. One or more solder balls 50a (e.g., a ball grid array (BGA)) may be formed on a side of the base die chiplet 50 that is opposite the first chiplet 100, which may allow the semiconductor device 1200 to be mounted to a substrate such as a packaging substrate.

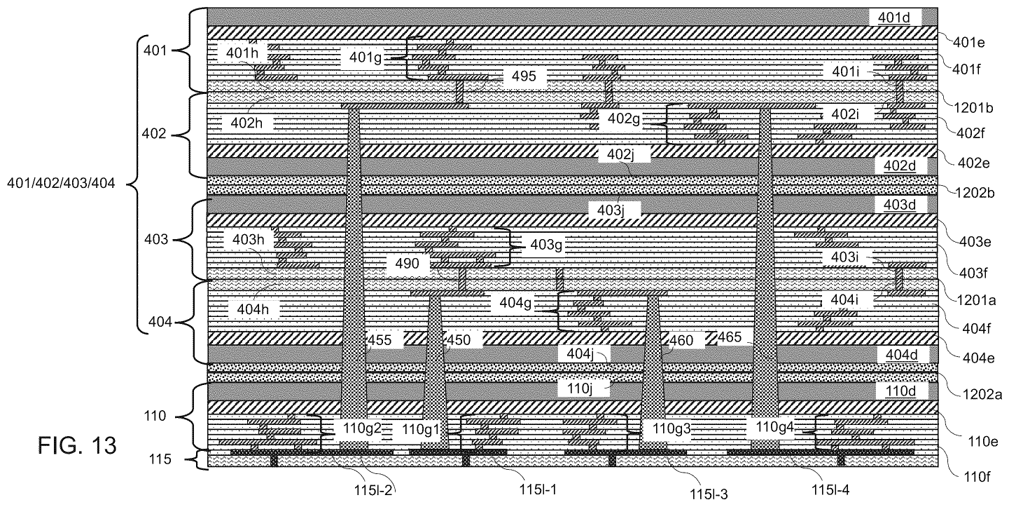

FIG. 13 is a vertical cross-sectional view of a fourth chiplet 400 (e.g., a 3D chiplet, top chiplet, etc.) according to one or more embodiments. The fourth chiplet 400 may be formed by a method that is similar to the method of forming the third chiplet 300 that is illustrated in FIGS. 10A-10L.

The fourth chiplet 400 may include the logic die 110 and a memory die stack 401/402/403/404 stacked on the logic die 110. The fourth chiplet 400 may also include the connecting structure 115 on the logic die 110.

The memory die stack 401/403/403/404 may include a first memory die 401, a second memory die 402, a third memory die 403 and a fourth memory die 404. The first memory die 401 may be inverted (so as to face the logic die 110) and include a semiconductor substrate 401d, an active region 401e on the semiconductor substrate 401d, an interlayer dielectric 401f on the active region 401e, one or more metal interconnect structures 401g in the interlayer dielectric 401f, a bonding material layer 401h on the interlayer dielectric 401f, and one or more bonding pads 402i in the bonding material layer 401h.

The second memory die 402 may include a semiconductor substrate 402d, an active region 402e on the semiconductor substrate 402d, an interlayer dielectric 402f on the active region 402e, one or more metal interconnect structures 402g in the interlayer dielectric 402f, a bonding material layer 402h on the interlayer dielectric 402f, and one or more bonding pads 402i in the bonding material layer 402h.

The third memory die 403 may be inverted and include a semiconductor substrate 403d, an active region 403e on the semiconductor substrate 403d, an interlayer dielectric 403f on the active region 403e, one or more metal interconnect structures 403g in the interlayer dielectric 403f, a bonding material layer 403h on the interlayer dielectric 403f, and one or more bonding pads 403i in the bonding material layer 403h.

The fourth memory die 404 may include a semiconductor substrate 404d, an active region 404e on the semiconductor substrate 404d, an interlayer dielectric 404f on the active region 404e, one or more metal interconnect structures 404g in the interlayer dielectric 404f, a bonding material layer 404h on the interlayer dielectric 404f, and one or more bonding pads 404i in the bonding material layer 404h.

In the memory die stack 401/402/403/404, the first memory die 401 may be direct bonded (e.g., WoW F2F bonded) to the second memory die 402 by a direct bond 1201b. In the direct bond 1201b, the bonding material layer 401h on the first memory die 401 may be direct bonded to the bonding material layer 402h on the second memory die 402, and the bonding pads 401i may be direct bonded to the bonding pads 402i (to form a bonding pad interconnect 495). The second memory die 402 may be bonded (e.g., WoW B2B bonded) to the third memory die 403 by an oxide bond 1202b between an oxide layer 402j on the second memory die 403 and the oxide layer 403j on the third memory die 403. The third memory die 403 may be direct bonded (e.g., WoW F2F bonded) to the fourth memory die 404 by a direct bond 1201a. In the direct bond 1201a, the bonding material layer 403h on the third memory die 403 may be direct bonded to the bonding material layer 404h on the fourth memory die 404, and the bonding pads 403i may be direct bonded to the bonding pads 404i. The memory die stack 401/402/403/404 may be bonded (e.g., WoW B2B bonded) to the logic die 110 by an oxide bond 1202a between an oxide layer 404j on the fourth memory die 404 and the oxide layer 110j on the logic die 110.

The fourth chiplet 400 may also include a first TSV 450, a second TSV 455, a third TSV 460 and a fourth TSV 465 that may provide an electrical connection within the fourth chiplet 400. The first TSV 450, second TSV 455, third TSV 460 and fourth TSV 465 may be the only TSVs in the fourth chiplet 400. That is, prior to the assembly of the fourth chiplet 400, there may be no TSVs in the first memory die 401, second memory die 402, third memory die 403, fourth memory die 404 or logic die 110.

The first TSV 450 may be located in the logic die 110 and extend across the oxide bond 1202a into the fourth memory die 404. The first TSV 450 may have a thickness in a z-direction in a range from about 1 μm to about 30 μm.

The first TSV 450 may contact a metal layer (e.g., metal trace) in the fourth memory die 404, and the metal layer may be connected across the direct bond 1201a to the metal interconnect structure 403g in the third memory die 403 by a connection between one or more bonding pads 404i and one or more bonding pads 403i. Thus, data may be transmitted to and from the active region 403e in the third memory die 403 by the first TSV 450.

The first TSV 450 may be connected by a metal layer 115g-1 of the connecting structure 115. The metal layer 115g-1 may also be connected to a metal interconnect structure 110g1 which is connected to the active region 110e in the logic die 110. Thus, the first TSV 450 may provide a data link between the third memory die 403 and the logic die 110.

The second TSV 455 may be located in the logic die 110 and extend across the oxide bond 1202a, the direct bond 1201a and the oxide bond 1202b into the second memory die 402. The second TSV 455 may have a thickness in a z-direction in a range from about 10 μm to about 50 μm.

The second TSV 455 may contact a metal layer (e.g., metal trace) in the second memory die 402, and the metal layer may be connected across the direct bond 1201b to the metal interconnect structure 401g in the first memory die 401 by a connection between one or more bonding pads 402i and one or more bonding pads 401i. Thus, data may be transmitted to and from the active region 401e in the first memory die 401 by the second TSV 455.

The second TSV 455 may also be connected by a metal layer 115g-2 of the connecting structure 115. The metal layer 115g-2 may be connected to a metal interconnect structure 110g2 which is connected to the active region 110e in the logic die 110. Thus, the second TSV 455 may provide a data link between the first memory die 401 and the logic die 110.

The third TSV 460 may be located in the logic die 110 and extend across the oxide bond 1202a into the fourth memory die 404. The third TSV 460 may have a thickness in a z-direction in a range from about 1 μm to about 30 μm.

The third TSV 460 may contact a metal layer (e.g., metal trace) in the metal interconnect structure 404g which is connected to the active region 404e of the fourth memory die 404. Thus, data may be transmitted to and from the active region 404e in the fourth memory die 404 by the third TSV 460.

The third TSV 460 may be connected by a metal layer 115g-3 of the connecting structure 115. The metal layer 115g-3 may also be connected to a metal interconnect structure 110g3 which is connected to the active region 110e in the logic die 110. Thus, the third TSV 460 may provide a data link between the fourth memory die 404 and the logic die 110.

The fourth TSV 465 may be located in the logic die 110 and extend across the oxide bond 1202a, the direct bond 1201a and the oxide bond 1202b into the second memory die 402. The fourth TSV 465 may have a thickness in a z-direction in a range from about 10 μm to about 50 μm.

The fourth TSV 465 may contact a metal layer (e.g., metal trace) in the metal interconnect structure 402g which is connected to the active region 402e of the second memory die 402. Thus, data may be transmitted to and from the active region 402e in the second memory die 402 by the fourth TSV 465.

The fourth TSV 465 may be connected by a metal layer 115g-4 of the connecting structure 115. The metal layer 115g-4 may also be connected to a metal interconnect structure 110g4 which is connected to the active region 110e in the logic die 110. Thus, the fourth TSV 465 may provide a data link between the second memory die 402 and the logic die 110.

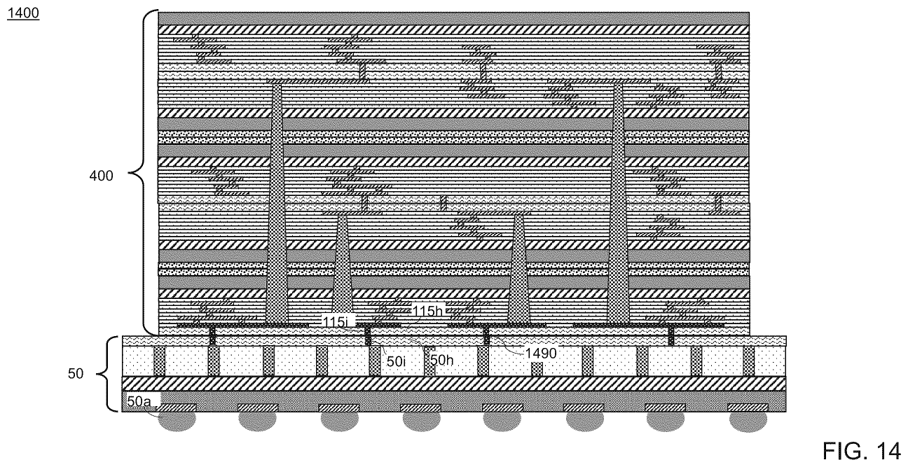

FIG. 14 is a vertical cross-sectional view of semiconductor device 1400 including the fourth chiplet 400, according to one or more embodiments. As illustrated in FIG. 14, semiconductor device 1400 may include the base die chiplet 50, and the fourth chiplet 400 (e.g., a chip-on-wafer (CoW) of the fourth chiplet 400) bonded to the base die chiplet 50. The fourth chiplet 400 (e.g., top die chiplet) can be WoW stacked memory and logic tiers, and may work as a co-processor, accelerator, or on-chip memory buffer for the base die chiplet 50.

In particular, the fourth chiplet 400 may be inverted so that the connecting structure 115 faces the base die chiplet 50. The fourth chiplet 400 may be bonded by a direct bond (e.g., hybrid bond) to the base die chiplet 50 so that that bonding material layer 115h of the fourth chiplet 400 is bonded to a bonding material layer 50h of the base die chiplet 50, and the bonding pad 115i of the fourth chiplet 400 is bonded to a bonding pad 50i of the base die chiplet 50 to form a bonding pad interconnect 1490. One or more solder balls 50a (e.g., a ball grid array (BGA)) may be formed on a side of the base die chiplet 50 that is opposite the first chiplet 100, which may allow the semiconductor device 1200 to be mounted to a substrate such as a packaging substrate.

Referring now to FIGS. 1-14, a semiconductor structure 100, 200, 300, 400 may include a logic die 110, a memory die stack 101/102, 201/202/203, 301/302/303/304, 401/402/403/404 bonded to the logic die 110 by a first oxide bond 1202, 1202a, and including a first pair of memory dies bonded together by a first direct bond 1201, 1201a, and a first through silicon via (TSV) 150, 250, 350, 450 in the logic die 110 and extending across the first oxide bond 1202, 1202a and electrically connecting the logic die 110 to the first pair of memory dies. In one embodiment, the first pair of memory dies may include a first memory die 101, and a second memory die 102 bonded to the first memory die 101 by the first direct bond 1201 and to the logic die 110 by the first oxide bond 1202. In one embodiment, the first TSV 150 may connect a metal layer in the logic die 110 to a metal layer in the second memory die 102. In one embodiment, the semiconductor structure 100 may further include a bonding pad interconnect 190 extending across the first direct bond 1201 and electrically connecting the first memory die 101 to the second memory die 102, wherein the first TSV 150 may be electrically connected to the first memory die 101 through the bonding pad interconnect 190. In one embodiment, the first direct bond 1201 between the first memory die 101 and the second memory die 102 may include a face-to-face bond, and the first oxide bond 1202 between the logic die 110 and the second memory die 102 may include a back-to-back oxide bond. In one embodiment, the first TSV 150 may include an exclusive data path between the first memory die 101 and the logic die 110, and between the second memory die 102 and the logic die 110.

In one embodiment, the memory die stack 201/202/203 may include a first memory die 201, a second memory die 202 bonded to the first memory die 201 by a second oxide bond 1202b, and a third memory die 203 bonded to the second memory die 202 and the logic die 110, wherein the first pair of memory dies may include the second memory die 202 and the third memory die 203. In one embodiment, the semiconductor structure 200 may further include a bonding pad interconnect 290 extending across the first direct bond 1201 and electrically connecting the second memory die 202 to the third memory die 203, wherein the first TSV 250 may be electrically connected to the second memory die 202 through the bonding pad interconnect 290. In one embodiment, the semiconductor structure 200 may further include a second through silicon via (TSV) 255 extending across the first oxide bond 1202a and across the first direct bond 1201, and across the second oxide bond 1202b, and electrically connecting the logic die 110 to the first memory die 201.

In one embodiment, the memory die stack 301/302/303 may include a first memory die 301, a second memory die 302 bonded to the first memory die 301 by a second direct bond 1201b, and a third memory die 303 bonded to the second memory die 302 by a second oxide bond 1202b, and a fourth memory die 304 bonded to the third memory die 303 and the logic die 110, wherein the first pair of memory dies may include the third memory die 303 and the fourth memory die 304. In one embodiment, the semiconductor structure 300 may further include a first bonding pad interconnect 390 extending across the first direct bond 1201a and electrically connecting the third memory die 303 to the fourth memory die 304, wherein the first TSV 350 may be electrically connected to the third memory die 303 through the first bonding pad interconnect 390. In one embodiment, the semiconductor structure 300 may further include a second through silicon via (TSV) 355 in the logic die 110 and extending across the first oxide bond 1202a, across the first direct bond 1201a, and across the second oxide bond 1202b, and electrically connecting the logic die 110 to the second memory die 302. In one embodiment, the semiconductor structure 300 may further include a second bonding pad interconnect 395 extending across the second direct bond 1201b and electrically connecting the first memory die 301 to the second memory die 302, wherein the second TSV 355 may be electrically connected to the first memory die 301 through the second bonding pad interconnect 395.

Referring now to FIGS. 1-3, a method of forming a semiconductor structure 100 may include forming a first direct bond 1201 between a first memory die 101 and a second memory die 102, connecting a first oxide layer 110j of a logic die 110 with a second oxide layer 102j of the second memory die 102, forming a first through silicon via (TSV) 150 in the logic die 110 so as to extend across the first and second oxide layers 110j, 102j and electrically connect the logic die 110 to the first memory die 101 and second memory die 102, and forming a metal layer on the first TSV 150 to connect the first TSV 150 to a logic circuit in the logic die 110.

In one embodiment, the second memory die 102 may include a metal interconnect structure 102g, and the forming of the first TSV 150 may include forming the first TSV 150 so as to contact the metal interconnect structure 102g. In one embodiment, the method may further include forming a connecting structure 115 on the logic die 110 and electrically connecting the logic die 110 to the first TSV 150.

Referring now to FIGS. 1-14, a semiconductor structure 400, 800, 1200, 1400 may include a base die chiplet 50, and a top die chiplet 100, 200, 300, 400 bonded to the base die chiplet 50. In one embodiment, the top die chiplet 100, 200, 300, 400 may include a logic die 110, a memory die stack 101/102, 201/202/203, 301/302/303/304, 401/402/403/404 bonded to the logic die 110 by a first oxide bond 1202, 1202a, and including a first pair of memory dies bonded together by a first direct bond 1201, 1201a, and a first through silicon via (TSV) 150, 250, 350, 450 in the logic die 110 and extending across the first oxide bond 1202, 1202a and electrically connecting the logic die 110 to the first pair of memory dies. In one embodiment, the top die chiplet 100, 200, 300, 400 may further include a connecting structure 115 on the logic die 110, the connecting structure 115 electrically connecting the logic die 110 to the first TSV 150, 250, 350, 450 and electrically connecting the top die chiplet 100, 200, 300, 400 to the base die chiplet 50. In one embodiment, the top die chiplet 100, 200, 300, 400 may be bonded to the base die chiplet 50 by a direct bond, and a bonding pad interconnect 490, 890, 1290, 1490 extends across the direct bond and electrically connects the top die chiplet 100, 200, 300, 400 to the base die chiplet 50.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a logic die;
a memory die stack bonded to the logic die by a first oxide bond, and including a first pair of memory dies bonded together by a first direct bond; and
a first through silicon via (TSV) in the logic die and extending across the first oxide bond and electrically connecting the logic die to the first pair of memory dies.

2. The semiconductor structure of claim 1, wherein the first pair of memory dies comprises a first memory die, and a second memory die bonded to the first memory die by the first direct bond and to the logic die by the first oxide bond.

3. The semiconductor structure of claim 2, wherein the first TSV connects a metal layer in the logic die to a metal layer in the second memory die.

4. The semiconductor structure of claim 2, further comprising:
a bonding pad interconnect extending across the first direct bond and electrically connecting the first memory die to the second memory die, wherein the first TSV is electrically connected to the first memory die through the bonding pad interconnect.

5. The semiconductor structure of claim 2, wherein the first direct bond between the first memory die and the second memory die comprises a face-to-face bond, and the first oxide bond between the logic die and the second memory die comprises a back-to-back oxide bond.

6. The semiconductor structure of claim 2, wherein at least one of:
the first memory die is devoid of an inner TSV extending through more than two dielectric layers of the first memory die to a dielectric layer in the second memory die; or
the second memory die is devoid of an inner TSV extending through more than two dielectric layers of second memory die to a dielectric layer in the first memory die.

7. The semiconductor structure of claim 1, wherein the memory die stack comprises
a first memory die;
a second memory die bonded to the first memory die by a second oxide bond; and
a third memory die bonded to the second memory die and the logic die, wherein the first pair of memory dies comprises the second memory die and the third memory die.

8. The semiconductor structure of claim 7, further comprising:
a bonding pad interconnect extending across the first direct bond and electrically connecting the second memory die to the third memory die, wherein the first TSV is electrically connected to the second memory die through the bonding pad interconnect.

9. The semiconductor structure of claim 7, further comprising:
a second through silicon via (TSV) extending across the first oxide bond and across the first direct bond, and across the second oxide bond, and electrically connecting the logic die to the first memory die.

10. The semiconductor structure of claim 1, wherein the memory die stack comprises:
a first memory die;
a second memory die bonded to the first memory die by a second direct bond;
a third memory die bonded to the second memory die by a second oxide bond; and
a fourth memory die bonded to the third memory die and the logic die, wherein the first pair of memory dies comprises the third memory die and the fourth memory die.

11. The semiconductor structure of claim 10, further comprising:
a first bonding pad interconnect extending across the first direct bond and electrically connecting the third memory die to the fourth memory die.

12. The semiconductor structure of claim 11, wherein the first TSV is electrically connected to the third memory die through the first bonding pad interconnect.

13. The semiconductor structure of claim 10, further comprising:
a second through silicon via (TSV) in the logic die and extending across the first oxide bond, across the first direct bond, and across the second oxide bond, and electrically connecting the logic die to the second memory die.

14. The semiconductor structure of claim 13, further comprising:
a second bonding pad interconnect extending across the second direct bond and electrically connecting the first memory die to the second memory die, wherein the second TSV is electrically connected to the first memory die through the second bonding pad interconnect.

15. A method of forming a semiconductor structure, the method comprising:
forming a first direct bond between a first memory die and a second memory die;
connecting a first oxide layer of a logic die with a second oxide layer of the second memory die;
forming a first through silicon via (TSV) in the logic die so as to extend across the first and second oxide layers and electrically connect the logic die to the first memory die and second memory die; and
forming a metal layer on the first TSV to connect the first TSV to a logic circuit in the logic die.

16. The method of claim 15, wherein the second memory die comprises a metal interconnect structure, and the forming of the first TSV comprises forming the first TSV so as to contact the metal interconnect structure.

17. The method of claim 15, further comprising:
forming a connecting structure on the logic die and electrically connecting the logic die to the first TSV.

18. A semiconductor structure, comprising:
a base die chiplet; and
a top die chiplet bonded to the base die chiplet, the top die chiplet comprising:
a logic die;
a memory die stack bonded to the logic die by a first oxide bond, and including a first pair of memory dies bonded together by a first direct bond; and
a first through silicon via (TSV) in the logic die and extending across the first oxide bond and electrically connecting the logic die to the first pair of memory dies.

19. The semiconductor structure of claim 18, wherein the top die chiplet further comprises a connecting structure on the logic die, the connecting structure electrically connecting the logic die to the first TSV and electrically connecting the top die chiplet to the base die chiplet.

20. The semiconductor structure of claim 19, wherein the top die chiplet is bonded to the base die chiplet by a direct bond, and a bonding pad interconnect extends across the direct bond and electrically connects the top die chiplet to the base die chiplet.
